(19) United States
(12) Patent Application Publication
(10) Pub. No.: US 2024/0184846 A1
(43) Pub. Date: Jun. 6, 2024

(54) METHODS AND APPARATUS TO ESTIMATE PRE-DISTORTION COEFFICIENTS

(71) Applicant: Texas Instruments Incorporated, Dallas, TX (US)

(72) Inventors: Mathews John, Bangalore (IN); Pankaj Gupta, Bangalore (IN); Jawaharlal Tangudu, Bangalore (IN); Pankaj Gaur, Bangalore (IN); Shikhar Chouhan, Bangalore (IN); Manchi Sankalkar Ajay, Bangalore (IN)

(21) Appl. No.: 18/129,589

(22) Filed: Mar. 31, 2023

(30) Foreign Application Priority Data
Dec. 6, 2022 (IN) 202241070222

(51) Int. Cl. G06F 17/16

(52) U.S. Cl. CPC G06F 17/16

(57) ABSTRACT

An example apparatus includes: programmable circuitry to receive an input signal, a digital pre-distorter (DPD) output signal, and a power amplifier (PA) feedback signal; populate a partial matrix with a threshold number of rows of equation terms; compute a respective observation terms for each row in the threshold number of rows; reduce the partial matrix into a Hermitian matrix and reduce the observation terms into a vector; accumulate the Hermitian matrix and the vector onto the memory; regularize, after a determination that a threshold number of Hermitian matrices have been accumulated, the memory to form an output matrix; and pre-distort the input signal using the output matrix.

### CROSS-REFERENCE TO RELATED APPLICATION

This patent application claims the benefit of and priority to Indian Provisional Patent Application Serial No. 202241070222 filed Dec. 6, 2022, which Application is hereby incorporated herein by reference in its entirety.

### TECHNICAL FIELD

This description relates generally to wireless communication, and more particularly to methods and apparatus to estimate pre-distortion coefficients.

### BACKGROUND

Wireless communications technology enables a wide variety of electronic devices (e.g., mobile phones, tablets, laptops, etc.) to support the execution of increasingly diverse and complex workloads. The secure, efficient, and accurate exchange of information over a wireless medium includes technical challenges. One such technical challenge is attenuation, which refers to the continued dissipation of a signal as it traverses a medium. In general, a signal will have more attenuation when crossing a wireless medium than it would when crossing a wired medium.

### SUMMARY

For methods and apparatus to estimate pre-distortion coefficients, an example device includes memory; machine-readable instructions; and programmable circuitry to at least one of instantiate or execute the machine-readable instructions to: receive an input signal, a digital pre-distorter (DPD) output signal, and a power amplifier (PA) feedback signal; populate a partial matrix with a plurality of rows of equation terms; compute a plurality of observation terms corresponding to the plurality of rows, the plurality of observation terms and the plurality of rows based on the input signal, the DPD output signal, and the PA feedback signal; determine whether the partial matrix includes a threshold number of rows; after a determination the partial matrix includes the threshold number of rows, reduce the partial matrix into a Hermitian matrix and reduce the observation terms into a vector; accumulate the Hermitian matrix and the vector onto the memory; and regularize, after a determination that a threshold number of Hermitian matrices have been accumulated, the memory to form an output matrix.

### BRIEF DESCRIPTION OF THE DRAWING

FIG. 1 is an example block diagram of a communication system.

FIG. 2 is an example block diagram of the transmitter circuitry of FIG. 1.

FIG. 3 is an example block diagram of the digital pre-distorter (DPD) circuitry of FIG. 2.

FIG. 4 is an example block diagram of the DPD estimator circuitry of FIG. 3.

FIG. 5 is an example block diagram of the row populator circuitry of FIG. 4.

FIG. 6A is a first example block diagram of the memory of FIG. 4

FIG. 6B is an example block diagram of the non-linear (NL) term populator circuitry of FIG. 5.

FIG. 7 is a second example block diagram of the memory of FIG. 4.

FIG. 8 is an example block diagram of the row reducer circuitry of FIG. 4.

FIG. 9 is a flowchart representative of a first example process that may be performed using machine-readable instructions that can be executed and/or hardware configured to implement the DPD estimator circuitry of FIG. 3, and/or, more generally, the DPD circuitry of FIG. 2 to determine a change to the DPD coefficients.

FIG. 10 is a flowchart representative of a second example process that may be performed using machine-readable instructions that can be executed and/or hardware configured to implement the DPD estimator circuitry of FIG. 3, and/or, more generally, the DPD circuitry of FIG. 2 to determine a change to the DPD coefficients.

FIG. 11 is a flowchart representative of an example process that may be performed using machine-readable instructions that can be executed and/or hardware configured to populate a row of a partial matrix as described in FIGS. 9 and 10.

FIG. 12 is a block diagram of an example processing platform including processor circuitry structured to execute the example machine-readable instructions and/or the example operations of FIGS. 9, 10, and 11 to implement the DPD estimator circuitry of FIG. 3.

The same reference numbers or other reference designators are used in the drawings to designate the same or similar (functionally and/or structurally) features.

### DETAILED DESCRIPTION

The drawings are not necessarily to scale. Generally, the same reference numbers in the drawing(s) and this description refer to the same or like parts. Although the drawings show regions with clean lines and boundaries, some or all of these lines and/or boundaries may be idealized. In reality, the boundaries and/or lines may be unobservable, blended and/or irregular.

To counteract signal attenuation, manufacturers may include power amplifier (PA) circuitry in a device to boost the power of a signal before transmission over a medium. In some examples, the PA circuitry operates at an improved efficiency (e.g., a higher ratio of output power to input power) when in a region of high nonlinearity instead of high linearity. In examples used herein, linearity refers to a measure of how well an input signal and a corresponding output signal can be linearly related (e.g., characterized using a linear equation).

While electronic devices can save power and resources by operating the PA circuitry at an improved efficiency, the resulting non-linear output signal can lead to increased adjacent channel leakage ratio (ACLR) and error vector magnitude (EVM). ACLR measures relative power at specified frequency offsets from an assigned channel of a transmitted signal with respect to the power transmitted within the assigned channel. EVM measures deviation of amplitudes and phase shifts of symbols in a transmitted signal from ideal constellation points. Accordingly, ACLR measures signal leakage outside an assigned frequency band, and EVM measures in-band signal quality loss. Therefore, an increase in ACLR or EVM results in a lower probability of a receiver properly decoding a received signal.

In some examples, manufacturers use DPD techniques to reduce the nonlinearity of PA circuitry while continuing to operate at an improved efficiency. In general, the nonlinear output caused by PA circuitry can be characterized as a function ƒ(x), where x is the original input signal and ƒ is a distorting function. DPD techniques counteract nonlinearity by applying an inverse function, ƒ⁻¹(x), to the original input signal and providing the output to the PA circuitry. In some examples, the application of the inverse function ƒ⁻¹ is referred to as a pre-distortion. As a result of the pre-distortion, the PA circuitry outputs an amplified version of ƒ(ƒ⁻¹(x))=x, which is the original input signal.

Manufacturers may use a wide variety of DPD equations to define an inverse function ƒ⁻¹. Two such examples are dynamic deviation reduction (DDR) equations and generalized memory polynomial (GMP) equations. In general, DDR equations leverage the fact that as an order of a term (e.g., x, x², x³, etc.) in the non-linear characterization of a PA circuit increases, the term has a smaller impact on the overall distortion caused by the PA circuit. As a result, a DDR equation can generate an accurate pre-distortion without the use of high-order terms.

Previous solutions to implement DPD equations may be inflexible in the sense that a given device only supports fixed terms in the equation (e.g., the non-linear characterization). Furthermore, previous solutions may also restrict the DPD equation to a specific set of terms computed in hardware or software, which eliminates the option for an end user to adjust the pre-distortion in a manner that best suits their particular use case.

Example methods, apparatus, and systems described herein describe example DPD estimator circuitry that determines an equation in an adjustable manner for use in pre-distortion. That is, example DPD circuitry described herein determines coefficients of an equation composed of individually adjustable terms. The example DPD estimator circuitry generates equations of various forms, including but not limited to a new DDR equation, an enhancement of a pre-existing DDR equation, or an equation similar to the DDR architecture (such as a GMP equation). For example, the DPD estimator circuitry can generate equation terms using either a PA modeling, indirect learning, or direct learning architecture. The example DPD estimator circuitry can generate a DPD equation using both pre-determined term formats and custom equation terms (i.e., terms with arbitrary formats that may not be included in some DPD polynomial formats). Furthermore, the example DPD estimator circuitry generates equation terms in an efficient manner that minimizes physical and/or virtual resources such as processor utilization, memory usage, and power consumption.

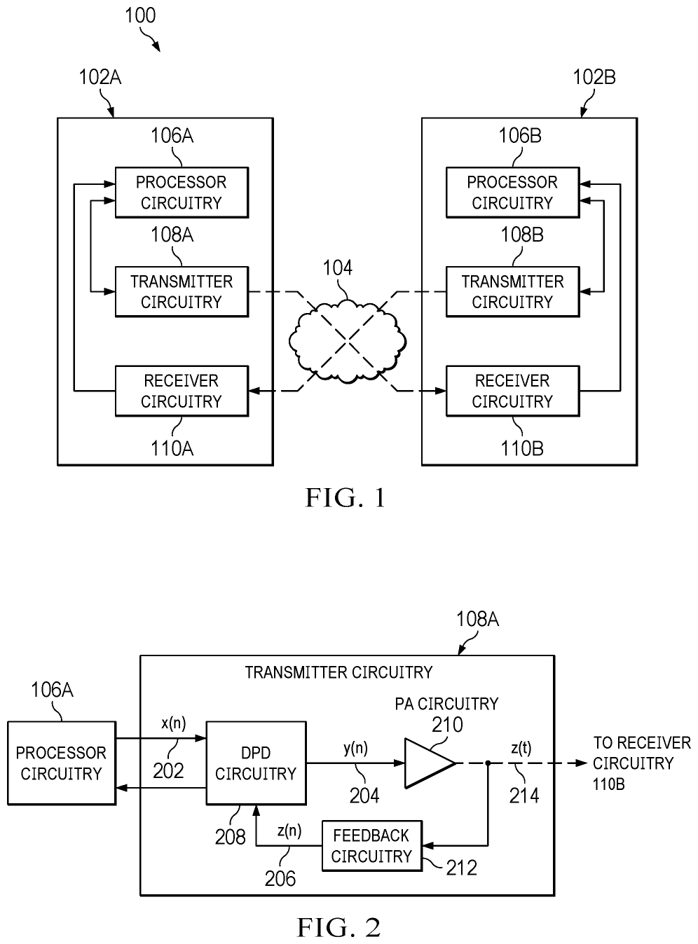

FIG. 1 is an example block diagram of a communication system. The example communication system 100 includes example devices 102A, 102B and an example wireless medium 104. The example device 102A includes example processor circuitry 106A, example transmitter circuitry 108A, and example receiver circuitry 110A. Similarly, the example device 102B includes example processor circuitry 106B, example transmitter circuitry 108B, and example receiver circuitry 110B.

The example devices 102A and 102B communicate with one another across a wireless medium 104. The example devices 102A and 102B may exchange any type of data and control signaling or messaging when communicating. For example, the device 102A may send a handshake message to the device 102B prior to sending the data. After receiving the handshake message, the device 102B may send an acknowledgement message to the device 102A. The example devices 102A and 102B may use any suitable protocol to communicate wirelessly, including but not limited to Wireless Fidelity (WiFi)®, Bluetooth®, Near Field Communication (NFC), Orthogonal Frequency-Division Multiplexing (OFDM), Code-Division Multiple Access (CDMA), etc. In some examples, the communication system 100 includes a wired medium (e.g., a cable) in addition to or instead of the wireless medium 104.

The example processor circuitry 106A receives data from a source (e.g., an internal memory, the device 102B, etc.) and performs operations based on the data. For example, the example processor circuitry 106A generates a digital input signal x(n) to be provided to the example device 102B. Similarly, the example processor circuitry 106B receives data from a source and performs operations based on the data. The example processor circuitry 106A and the example processor circuitry 106B may be any type of processor circuitry. Examples of processor circuitry include programmable microprocessors, Field Programmable Gate Arrays (FPGAs) that may instantiate instructions, Central Processor Units (CPUs), Graphics Processor Units (GPUs), Digital Signal Processors (DSPs), or microcontrollers and integrated circuits such as Application Specific Integrated Circuits (ASICs).

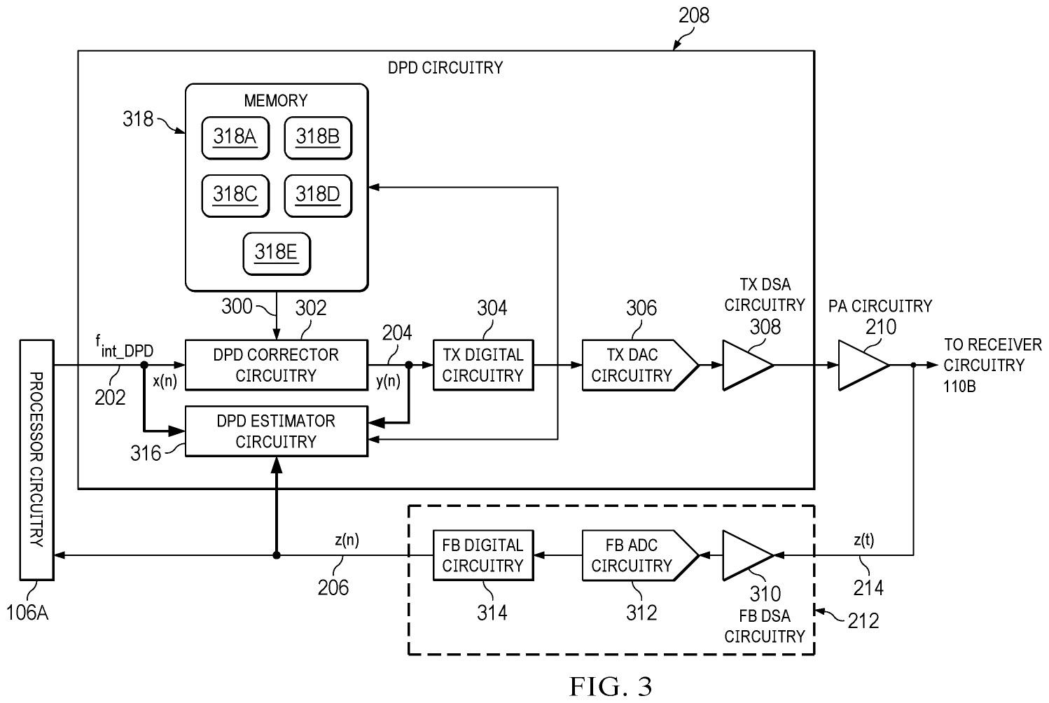

The example transmitter circuitry 108A and the example transmitter circuitry 108B receive digital signals from the example processor circuitry 106A and the example processor circuitry 106B, respectively. The example transmitter circuitry 108A and 108B both pre-distort digital signals according to this description, convert the digital signals into analog signals, amplify the power in the analog signal, and send the amplified signal over the wireless medium 104. The example transmitter circuitry 108A is described further in connection with FIG. 2.

The example receiver circuitry 110A receives the analog signal transmitted by the transmitter circuitry 108B. The example receiver circuitry 110A converts the analog signal into a digital signal and provides the digital signal to the processor circuitry 106A. Similarly, the example receiver circuitry 110B receives the analog signal transmitted by the transmitter circuitry 108A. The example receiver circuitry 110B converts the analog signal into a digital signal and provides the digital signal to the processor circuitry 106B.

In the example communication system 100, the example transmitter circuitry 108A and example transmitter circuitry 108B are implemented with example DPD estimator circuitry that determines coefficients of an equation according to the teachings of this description. As a result, the one or more manufacturers or users of the example devices 102A, 102B has more options to adjust the equation than previous solutions, leading to a more efficient exchange of data between the devices 102A, 102B than previous implementations of DPD equations.

FIG. 2 is an example block diagram of the transmitter circuitry 108A of FIG. 1. The example transmitter circuitry 108A includes example DPD circuitry 208, example PA circuitry 210, and example feedback circuitry 212. Signals used by, generated in, or generated by the transmitter circuitry 108A include an example x(n) signal 202, an example y(n) signal 204, an example z(n) signal 206, and an example z(t) signal 214.

The example x(n) signal 202 represents a digital input signal. For example, the x(n) signal 202 in the foregoing example of FIG. 1 is a handshake message. The example y(n) signal 204 is a pre-distorted version of the input signal, x(n). The example z(n) signal 206 is a digital version of the analog z(t) signal 214. The example z(t) signal 214 is an analog output signal generated by the PA circuitry 210. As described further below, the analog z(t) signal 214 is provided to an antenna (not shown) of the transmitter circuitry 108A for transmission across the wireless medium 104, and the digital z(n) signal 206 is used to adjust the digital y(n) signal 204.

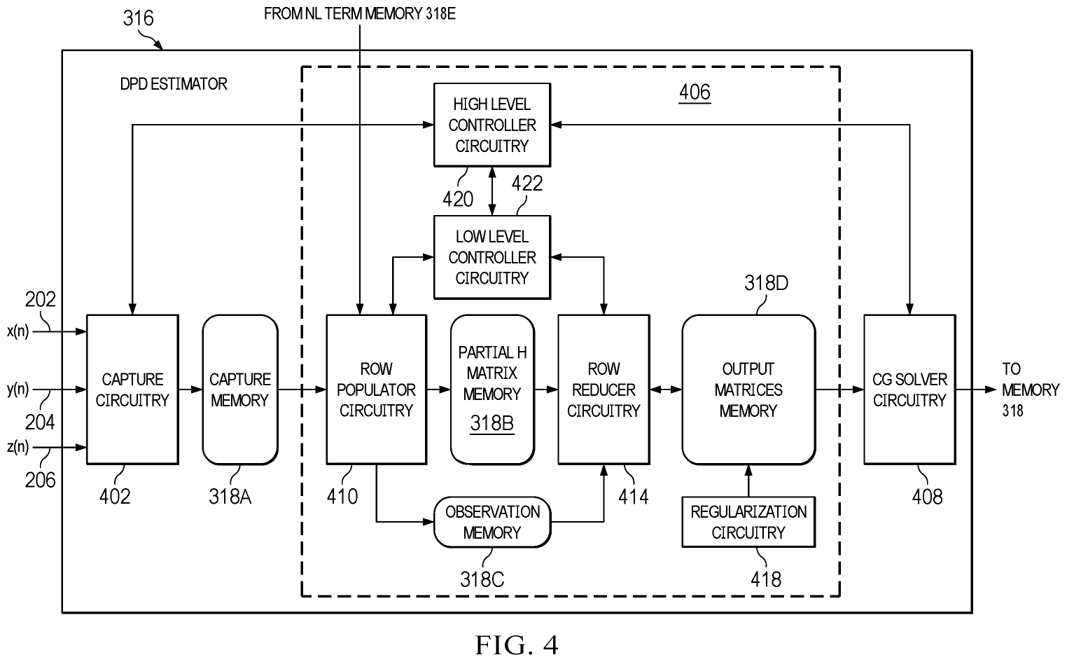

The example DPD circuitry 208 receives the x(n) signal 202 from the processor circuitry 106A and receives the z(n) signal 206 from the PA circuitry 210. The example DPD circuitry 208 uses the x(n) signal 202 and the z(n) signal 206 to generate the y(n) signal 204. For example, example DPD corrector circuitry 302 (shown in FIG. 3) generates the y(n) signal 204 using a DPD equation such as equation (1):

y(n)=Σᵣ₌₁^{NCoeff}Cᵣ×linear term(x(n−l₁(r)))×key term(x(n−l₃(r)))×basis function term(|x(n−l₂(r))|) (1)

An example implementation of equation (1) is given by equation (1A):

y(n)=Σᵣ₌₁^{NCoeff1}C₁(r)×x(n−l_{1,1}(r))×bₖ_{₁}₍ᵣ₎(|x(n−l_{2,1}(r))|)+Σᵣ₌₁^{NCoeff2}C₂(r)×conj[x(n−l_{1,2}(r))]×x²(n−l_{3,2}(r))×bₓ_{₂}₍ᵣ₎(|x(n−l_{2,2}(r))|)+Σᵣ₌₁^{NCoeff3}C₃(r)×x(n−l_{1,3}(r)×|x(n−l_{3,3}(r))|²×bₖ_{₃}₍ᵣ₎(|x(n−l_{2,3}(r))|) (1A)

In equation (1A), x(n−l_{1,1}(r)), conj[x(n−l_{1,2}(r))], and x(n−l_{1,3}(r)) are linear terms, x²(n−l_{3,2}(r)) and |x(n−l_{3,3}(r))|² are key terms, and bₖ_{₁}₍ᵣ₎(|x(n−l_{2,1}(r))|). bₖ_{₂}₍ᵣ₎(|x(n−l_{2,2}(r))|), and bₖ_{₃}₍ᵣ₎(|x(n−l_{2,3}(r))|) are basis function terms. Within each of the linear terms, the key terms, and the basis function terms, the values l_{1,1}(r), l_{2,1}(r), l_{1,2}(r), l_{3,2}(r), l_{2,2}(r), l_{3,3}(r), l_{1,3}(r) and l_{2,3}(r) are lag terms that are specific to a particular type of PA circuitry and can be pre-determined and stored before the original input signal x(n) is received. Similarly, because bₖ_{₁}₍ᵣ₎, bₖ_{₂}₍ᵣ₎, and bₖ_{₃}₍ᵣ₎ are real-valued complex polynomials describing the nonlinear response of PA circuitry, the polynomials can be pre-determined and stored before the original input signal x(n) is received. For example, bₖ_{₁}₍ᵣ₎, bₖ_{₂}₍ᵣ₎, and bₖ_{₃}₍ᵣ₎ may be pre-determined in a factory or characterization lab. In some examples, bₖ_{₁}₍ᵣ₎, bₖ_{₂}₍ᵣ₎, and bₖ_{₃}₍ᵣ₎ are referred to as basis functions.

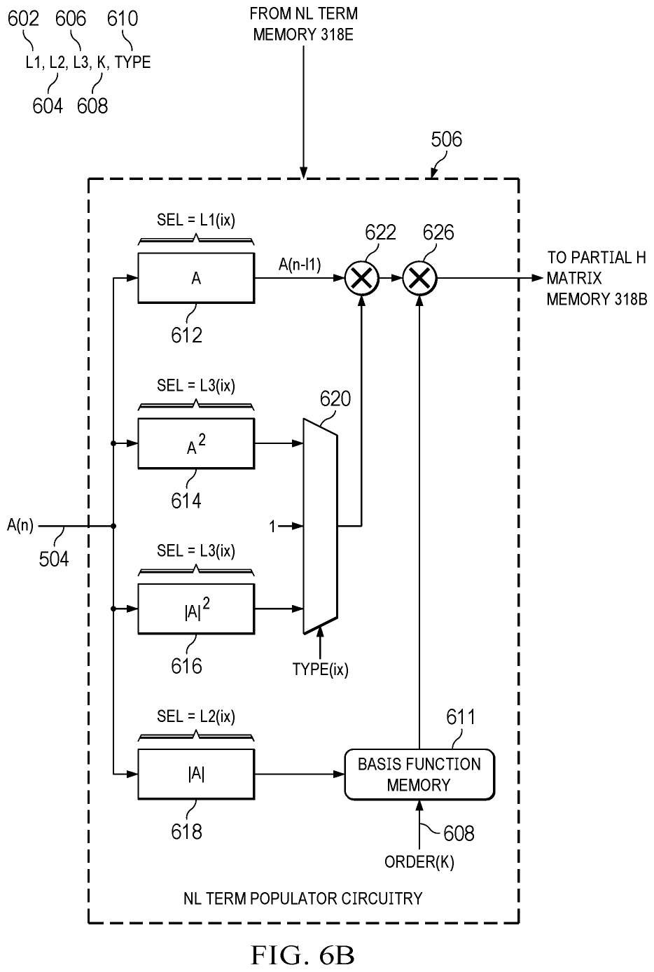

The lag terms and basis functions described in equation (1A) are described further below in connection with FIG. 6B. The c₁(r), c₂(r), and c₃(r) terms in equation (1A) are coefficients that are estimated by the DPD circuitry 208. The coefficients are described further in connection with FIGS. 3 and 6. While equation (1A) is one implementation of equation (1), all example implementations of equation (1) also include coefficients, lag terms, and basis functions.

Equation (1A) is an example implementation of a DPD equation with a three summation architecture. As used herein, any terms that are included in the first summation of such a DPD equation are referred to as type-1 terms. For example, in equation (1A), x(n−l_{1,1}(r)) and bₖ_{₁}₍ᵣ₎(|x(n−l_{2,1}(r))|) are type-1 terms. Similarly, as used herein, any terms that are included in the second summation of such a DPD equation are referred to as type-2 terms. For example, in equation (1A), conj[x(n−l_{1,2}(r))], x²(n−l_{3,2}(r)), and bₖ_{₂}₍ᵣ₎(|x(n−l_{2,2}(r))|) are type-2 terms. Finally, as used herein, terms that are included in the third summation of such a DPD equation are referred to as type-3 terms. For example, in equation (1A), |x(n−l_{3,3}(r))|², x(n−l_{1,3}(r)), and bₖ_{₃}₍ᵣ₎(|x(n−l_{2,3}(r)|) are type-3 terms.

Equation (1A) includes a complex conjugate of the type-2 linear term, conj[x(n−l_{1,2}(r)]. In other example implementations of a three summation DPD equation, a type-2 linear term is directly utilized. Some other example implementations of equation (1) are realized with only type-1 term linear terms (i.e., only one summation). Such example implementations may be referred to as a GMP equation. Accordingly, in some examples, type-1 terms are also referred to as GMP terms. The example DPD circuitry 208 is described further in connection with FIG. 3.

The example PA circuitry 210 amplifies the y(n) signal 204 to generate an analog output z(t) signal, which is strong enough to sustain the signal attenuation across the wireless medium 104 and contain interpretable data when received at the receiver circuitry 110B. The PA circuitry 210 provides the z(t) signal 214 to an antenna for transmission.

The example feedback circuitry 212 receives a copy of the analog z(t) signal 214 and uses the copy to generate the digital z(n) signal 206. The feedback circuitry 212 also provides the z(n) signal 206 to the DPD circuitry 208. The feedback circuitry 212 and the z(n) signal 206 are described further in FIG. 3.

FIG. 3 is an example block diagram of the digital pre-distorter (DPD) circuitry of FIG. 2. FIG. 3 includes the DPD circuitry 208, the example PA circuitry 210, and the feedback circuitry 212. The example DPD circuitry 208 includes example DPD corrector circuitry 302, example transmission (TX) digital circuitry 304, example TX digital to analog converter (DAC) circuitry 306, example TX digital step attenuator (DSA) circuitry 308, example DPD estimator circuitry 316, and example memory 318. The feedback circuitry 212 includes example feedback (FB) DSA circuitry 310, example FB analog to digital converter (ADC) circuitry 312, and example FB digital circuitry 314. Signals used by, generated in, or generated by the DPD circuitry 208 include the example x(n) signal 202, the example y(n) signal 204, and the example z(n) signal 206.

The example DPD corrector circuitry 302 generates the example y(n) signal 204 following the format described in equation (1). To do so, the example DPD circuitry 208 samples the x(n) signal 202 provided by the processor circuitry 106A and receives the lag terms and basis functions of equation (1) from the example memory 318. In some examples, the DPD corrector circuitry 302 also determines the values of c₁(r), c₂(r), and c₃(r) from equation (1) based on information provided by the DPD estimator circuitry 316. In other examples, the DPD corrector circuitry 302 receives the values of c₁(r), c₂(r), and c₃(r) from the DPD estimator circuitry 316 and uses the coefficients to determine the y(n) signal 204.

The example TX digital circuitry 304 interpolates the example y(n) signal 204 to introduce additional data points. The additional data points increase the sample rate of the y(n) signal 204 relative to the sample rate of the x(n) signal 202. The example TX digital circuitry 304 both a) ensures that the frequency of information in the output signal z(n) signal 206 is sufficiently high so that the receiver circuitry 110B can recover the information, and b) allows the DPD corrector circuitry 302 to only sample the signal for pre-distortion when necessary (e.g., at a relatively lower frequency).

The example TX DAC circuitry 306 converts the interpolated y(n) signal 204 from a digital signal to an analog signal. As a result, information transmitted across the wireless medium 104 is encoded continuously across a range of voltages rather than a discrete set of voltages.

The example TX DSA circuitry 308 attenuates the interpolated y(n) signal 204 so that the PA circuitry 210 consumes a consistent amount of power. In particular, the TX DSA circuitry 308 attenuates the interpolated y(n) signal 204 based on the gain of the PA circuitry 210, which may change based on temperature. The example TX DSA circuitry 308 provides the interpolated and attenuated y(n) signal 204 to the example PA circuitry 210, which amplifies the signal for transmission to the receiver circuitry 110B.

Within the feedback circuitry 212, the example FB DSA circuitry 310 receives the analog output z(t) signal 214 from the PA circuitry 210 and attenuates the signal. In some examples, the FB DSA circuitry 310 attenuates the analog output z(t) signal 214 based on the operating parameters of the FB ADC circuitry 312.

Within the feedback circuitry 212, the example FB ADC circuitry 312 converts the attenuated output z(t) signal 214 from an analog signal to a digital signal z(n) signal 206. The example FB digital circuitry 314 then decimates (e.g., removes data points from) the digital signal. As a result, the digital z(n) signal 206 can be fed back to and interpreted by both the example DPD estimator circuitry 316 (within the DPD circuitry 208) and the processor circuitry 106A.

When operating in a high efficiency range, the PA circuitry 210 both amplifies and distorts the interpolated, analog, and attenuated y(n) signal 204. The example DPD corrector circuitry 302, therefore, operates to pre-distort the input x(n) signal 202 and generates the y(n) signal 204 such that the digital, decimated, and attenuated output z(n) signal 206 provided to the DPD estimator circuitry 316 is equal to or is substantially equal to the original input x(n) signal 202. The example DPD corrector circuitry 302 also pre-distorts the input x(n) signal 202 so that the analog output z(t) signal 214 transmitted over the wireless medium 104 is a scaled, analog, and linear version of the x(n) signal 202.

In an example, the DPD corrector circuitry 302 generates the y(n) signal 204 following the format in equation (1). The coefficients within any implementation of equation (1) may not be directly computable because the values may change over time based on the contents of the x(n) signal 202. The computation of the coefficients, therefore, is an iterative process that minimizes the error e(n) between the original input x(n) signal 202 and the digital, decimated, and attenuated output z(n) signal 206. In some examples, the DPD corrector circuitry 302 assigns pre-determined values to c₁(r), c₂(r), and c₃(r) initially. In such examples, the example DPD estimator circuitry 316 then generates multiple sets of coefficient deltas sequentially. A given set of coefficients describe changes to c₁(r), c₂(r), and c₃(r) that result in the value of e(n) coming closer to zero. In an example, the DPD corrector circuitry 302 implements equation (2) and the DPD estimator circuitry 316 implements equation (3) as provided:

$${c}_{k} = {c}_{k - 1} + Δ {c}_{k} \qquad ( 2 )$$

$$Δ {c}_{k} = \frac{{( {H}^{H} H )}^{- 1} ( {H}^{H} E )}{{G}_{k}} \qquad ( 3 )$$

In equation (2), cₖ refers to the value of a coefficient (e.g., any of c₁(r), c₂(r), and c₃(r)) at time k·cₖ₋₁ refers to the value of the same coefficient at time k−1, and Δcₖ is a coefficient delta describing how cₖ differs from cₖ₋₁. When the x(n) signal 202 is sampled, the DPD corrector circuitry receives a set of Δcₖ terms and adds the Δcₖ terms to c₁(r), c₂(r), and c₃(r) to use in determining the y(n) signal 204.

In equation (3), Gₖ is the gain of the PA circuitry 210, and E is the error signal e(n) between the original input x(n) signal 202 and the digital, decimated, and attenuated output z(n) signal 206. Equation (3) also includes H, which is a matrix of equation terms formed by the example DPD estimator circuitry 316. The DPD estimator circuitry 316 uses components of the H matrix to compute the H^{H}H and H^{H} E matrices. The H^{H} H matrix refers to a regularized and invertible matrix of equations terms. Similarly, the H^{H} E matrix refers to error values that correspond to the equation terms in the H^{H} H matrix. As used above and herein, the H matrix refers to the set of data used by the example DPD estimator circuitry 316 to compute the H^{H} H and H^{H} E matrices in equation (3).

Techniques to efficiently calculate Δcₖ, given already completed H^{H} H and H^{H} E matrices, are described in U.S. patent application Ser. No. 17/977,813, which is herein incorporated by reference in its entirety. Advantageously, example methods, apparatus, and systems described herein provide efficient techniques for the example DPD estimator circuitry 316 to efficiently compute the H^{H} H and H^{H} E matrices, thereby further reducing compute time and resource consumption when compared to previous solutions. In some examples, the DPD estimator circuitry 316 may implement both equations (2) and (3) as described above.

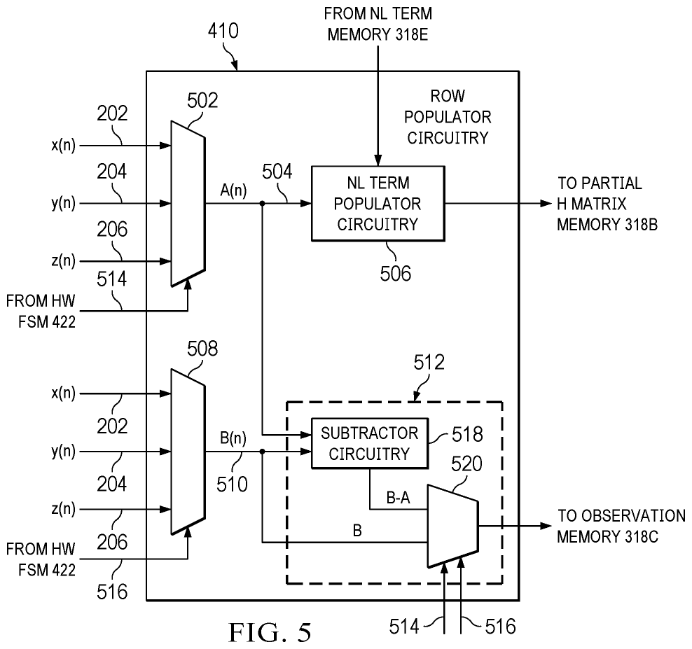

The example memory 318 stores data used by the example DPD circuitry 208 to receive, generate, and analyze the x(n) signal 202, the y(n) signal 204, and the z(n) signal 206, respectively. In examples described herein, the memory 318 includes various sections, including but not limited to example capture memory 318A, example partial H matrix memory 318B, example observation memory 318C, example output matrices memory 318D, and example NL term memory 318E. The DPD circuitry 208 stores different data in each of the sections of the memory 318. For example, the DPD circuitry 208 stores the pre-determinable lag terms and basis functions corresponding to a selected implementation of equation (1) within the NL term memory 318E. The contents of the example memory 318 are described further in connection with FIGS. 4, 6A, and 7.

The example memory 318 also stores the coefficients of the selected implementation and additional data structures used by the DPD circuitry 208 to determine the coefficients 300 (e.g., the Δcₖ values and the H matrix from equations (2) and (3)). In particular, the example DPD estimator circuitry 316 accesses the memory 318 to compute the H matrix and to determine the Δcₖ terms. The example DPD estimator circuitry 316 then stores the Δcₖ in memory 318, which the DPD corrector circuitry 302 then uses to adjust the DPD equation.

The example memory 318 may be implemented as any type of memory. For example, the example memory 318 includes both volatile memory and non-volatile memory. The volatile memory may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory may be implemented by flash memory and/or any other desired type of memory device.

In some examples, one or more portions of the memory 318 is implemented as a database. In such examples, the one or more portions of the memory 318 is implemented by any memory, storage device and/or storage disc for storing data such as, flash memory, magnetic media, optical media, solid state memory, hard drive(s), thumb drive(s), etc. Furthermore, the data stored in the one or more portions of the memory 318 may be in any data format such as, binary data, comma delimited data, tab delimited data, structured query language (SQL) structures, etc. While the memory 318 is illustrated in FIG. 3 as a single device, the memory 318 and/or any other data storage devices described herein may be implemented by any number and/or type(s) of memories.

FIG. 4 is an example block diagram of the DPD estimator circuitry 316 of FIG. 3. The example DPD estimator circuitry 316 includes example capture circuitry 402, the example capture memory 318A, example matrix populator circuitry 406, and example conjugate gradient (CG) solver circuitry 408. The example matrix populator circuitry 406 includes example row populator circuitry 410, an example partial H matrix memory 318B, example row reducer circuitry 414, the example output matrices memory 318D, example regularization circuitry 418, example high level controller circuitry 420, and example low level controller circuitry 422.

The example capture circuitry 402 samples the digital input x(n) signal 202, the pre-distorted example y(n) signal 204, and the feedback signal z(n) signal 206. In some examples, the sampling performed by the example capture circuitry 402 is based on clock circuitry. The clock circuitry may be implemented in any location within the device 102A.

The example capture circuitry 402 stores the samples in the example capture memory 318A. The example capture memory 318A may be implemented by any type of memory. While illustrated as an internal component of the DPD estimator circuitry 316 in the example of FIG. 4, in other examples, the capture memory 318A is a component of the example memory 318. In another example, the capture circuitry 402 and capture memory 318A is implemented in digital logic circuitry, which may include one or more synchronous or asynchronous logic devices.

The example matrix populator circuitry 406 uses the samples in the capture memory 318A to efficiently compute the H^{H} H and H^{H} E matrices from equation (3) as described in the teachings of this description. The example CG solver circuitry 408 then receives H^{H} H and H^{H} E matrices from the matrix populator circuitry 406 and uses them to efficiently compute Δcₖ, as described in U.S. patent application Ser. No. 17/977,813. In other examples, a different linear equation solver is used to compute Δcₖ instead of the example CG solver circuitry 408.

Within the example matrix populator circuitry 406, the example row populator circuitry 410 populates rows of the H matrix. To do so, the example matrix populator circuitry 406 receives samples from the capture memory 318A and lag terms from the example NL term memory 318E. The row populator circuitry 410 uses the data to populate a row of the H matrix, which contains the terms used to solve or compute one equation corresponding to the format of equation (1). The example row populator circuitry 410 also uses the data to populate the observation memory 318C.

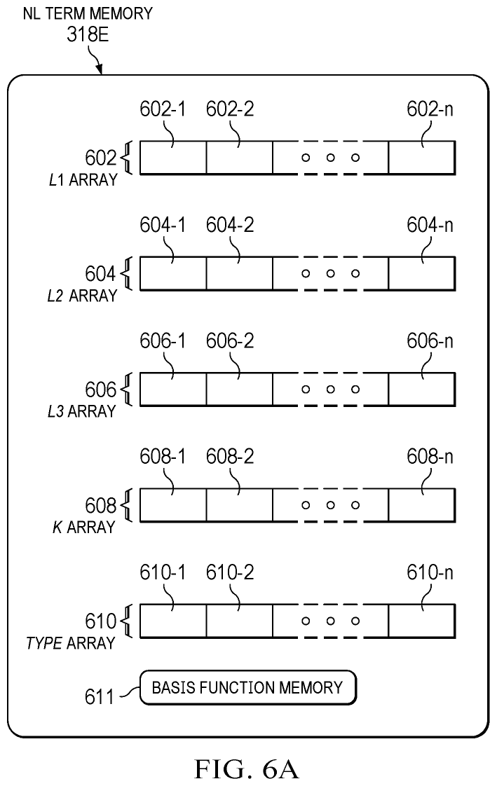

The row populator circuitry 410 stores a threshold number, P, rows of the H matrix within the partial H matrix memory 318B. In examples, each row stored within the partial H matrix memory 318B corresponds to a single instance of time such that an equation in row 1 corresponds to a first sample of the input signal; an equation in row 2 corresponds to a second sample of the input signal; and the second sample occurs after the first sample. The example row populator circuitry 410 is described further in connection with FIGS. 5, 6, and 11.

The example partial H matrix memory 318B is an incomplete version of the H matrix used in equation (3). The example partial H matrix memory 318B may be stored in any type of memory. The partial H matrix memory 318B is illustrated as an internal component of the DPD estimator circuitry 316 in the example of FIG. 4 for simplicity. In examples used above and herein, the partial H matrix memory 318B is a portion the example memory 318.

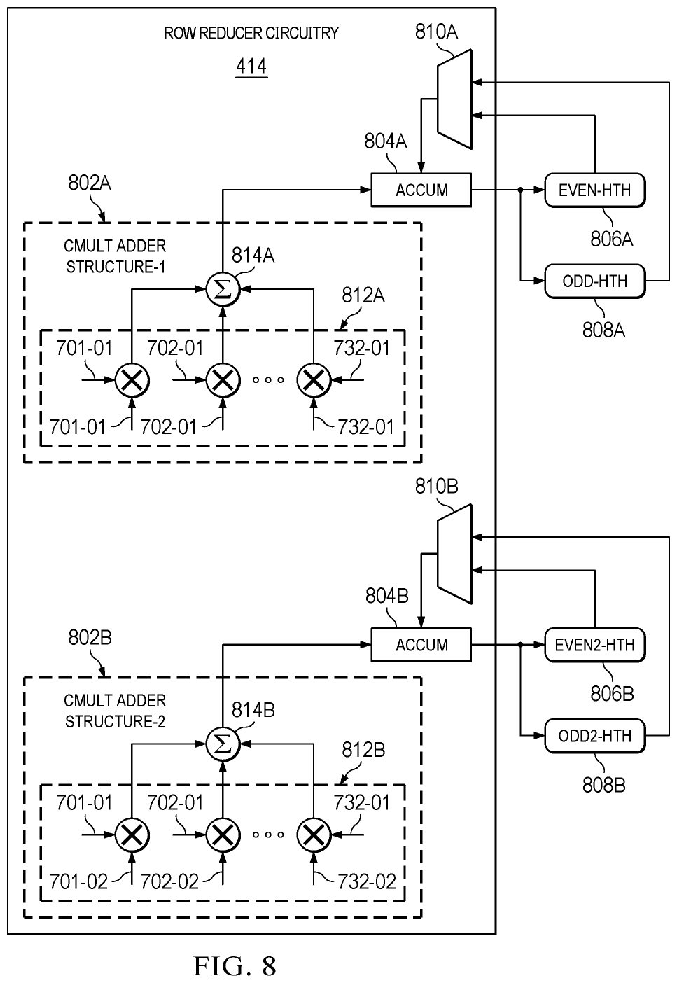

The example observation memory 318C stores observation terms populated by the example row populator circuitry 410. As used above and herein, observation terms refer to values used by the row reducer circuitry 414 to determine the H^{H} E matrix from equation (3). The example observation memory 318C is described further in connection with FIGS. 5 and 8.

Within the example matrix populator circuitry 406, the example row reducer circuitry 414 receives the row data stored within the partial H matrix memory 318B. The example row reducer circuitry 414 performs reduction operations to transform the P rows stored within of the partial H matrix memory 318B into a version of the H^{H} H matrix of equation (3).

The example row reducer circuitry 414 also receives observation terms from the observation memory 318C and performs reduction operations with the observation terms to form a version of the H^{H} E matrix of equation (3). The example row reducer circuitry 414 is described further in connection with FIG. 8.

Within the example matrix populator circuitry 406, the output matrices memory 318D stores a single version of an H^{H} H matrix of equation (3) and a single version of an H^{H} E matrix of equation (3). In particular, one matrix stored in the output matrices memory 318D is an accumulated version of all previous H^{H} H matrices formed by the example row reducer circuitry 414. Similarly, the other matrix stored in the output matrices memory 318D is an accumulated version of all operations performed by the example row reducer circuitry 414 to compute the H^{H} E matrix. The example output matrices memory 318D may be implemented by any type of memory. The output matrices memory 318D is illustrated as an internal component of the DPD estimator circuitry 316 in the example of FIG. 4 for simplicity. In examples described above and herein, the output matrices memory 318D is a component of the memory 318.

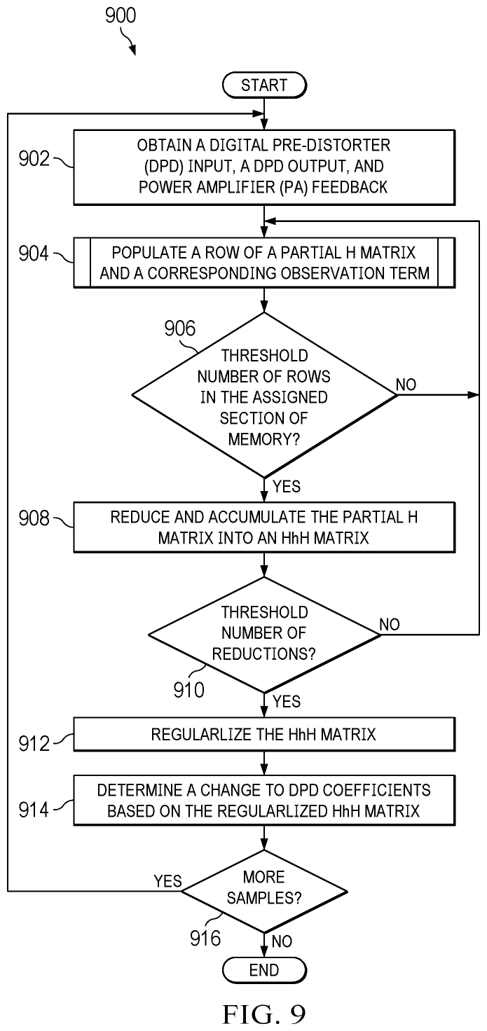

Within the example matrix populator circuitry 406, the example regularization circuitry 418 adds regularization terms to the H^{H} H matrix in the output matrices memory 318D. The regularization terms help to increase the rank of the H^{H} H matrix in the example output matrices memory 318D, which enables the CG solver circuitry 408 to invert the H^{H} H matrix as described in equation (3). The example regularization circuitry 418 is described further in connection with FIG. 9.

Within the example matrix populator circuitry 406, the example high level controller circuitry 420 and the example low level controller circuitry 422 coordinate the operations of the other components within the DPD estimator circuitry 316. For example, the high level controller circuitry 420 controls: when the capture circuitry 402 samples the signals, when the row reducer circuitry 414 accumulates one version of an H^{H} H matrix into the output matrices memory 318D, and when the regularization circuitry 418 adds regularization terms. Additionally, the example low level controller circuitry 422 monitors the row populator circuitry 410 to determine when the threshold P number of rows have been formed in the partial H matrix 412 and subsequently signals the row reducer circuitry 414 to perform reduction operations.

In some examples, the high level controller circuitry 420 may perform operations at a lower frequency than the example low level controller circuitry 422. In such examples, the DPD estimator circuitry 316 may implement two clock signals with different frequencies because the operations performed by the high level controller circuitry 420 are less time sensitive than the low level controller circuitry 422. Accordingly, the computational resources used to support a relatively fast clock signal and implement the low level controller circuitry 422 are unnecessary for the implementation of the high level controller circuitry 420.

The example high level controller circuitry 420 and the example low level controller circuitry 422 may be any type of processor circuitry. Examples of processor circuitry include programmable microprocessors, Field Programmable Gate Arrays (FPGAs) that may instantiate instructions, Central Processor Units (CPUs), Graphics Processor Units (GPUs), Digital Signal Processors (DSPs), XPUs, or microcontrollers and integrated circuits such as Application Specific Integrated Circuits (ASICs). The example high level controller circuitry 420 and the example low level controller circuitry 422 are described further in connection with FIGS. 9-11.

In practice, the CG solver circuitry 408 may generate a single set of Δcₖ values using H^{H} H and H^{H} E matrices that both have approximate dimensions of 500×500. This means both H^{H} H and H^{H} E matrices describe a set of 500 DPD equations that each have 500 terms. Furthermore, the example capture circuitry 402 may record approximately 20,000 samples before providing the H^{H} H and H^{H} E matrices stored within the example output matrices memory 318D to the CG solver circuitry 408. The example capture circuitry 402 may record the 20,000 samples over any length of time. In such an example, the H matrix of equation (3), if stored in its entirety, would have approximate dimensions of 20,000×500 (i.e., 20,000 rows and 500 columns). Such an H matrix corresponds to 20,000 equations of a specified form that each have 500 terms. Similarly, the error vector E would have approximate dimensions of 20,000×1. In such examples, the vector E corresponds to one error value, equal to the difference between the sampled x(n) signal 204 and sampled z(n) signal 206, for each of the 20,000 DPD equations. Accordingly, in some examples, the H^{H} E matrix may also be referred to as a vector because it also has a dimension of length 1.

In the foregoing example, the completed H matrix of equation (3) would contain approximately 10 million elements. As such, storing the entirety of the H matrix would be both impractical and inefficient. Advantageously, the example DPD estimator circuitry 316 does not store the entire H matrix at any one point in time, but rather stores the partial H matrix memory 318B. In particular, the partial H matrix only contains P rows, which may be substantially less than 20,000.

In a hypothetical where P=1, the size of the partial H matrix memory 318B would be minimized as the corresponding portion of memory 318 would only store approximately 500 terms corresponding to one DPD equation at any point time. In the P=1 hypothetical, however, the example row reducer circuitry 414 would perform

$$\frac{20 , 000}{P} = 20 , 000$$

row reduction operations, resulting in 20,000 versions of an H^{H} H matrix that would need an additional 20,000 accumulations to form one finalized H^{H} H matrix in the output matrices memory 318D. In some examples, the finalized H^{H} H matrix in the example H^{H} H matrix memory 416 is referred to as an output matrix. In many examples, 20,000 row reduction operations and 20,000 accumulations would be considered inefficient from both a compute time and resource utilization perspective. Advantageously, the example DPD estimator circuitry 316 supports an adjustable P value rather than a fixed number. As a result, a manufacturer and user can select a value of P that optimally balances the size of the partial H matrix memory 318B and the resource drain of operations from the row reducer circuitry 414.

FIG. 5 is an example block diagram of the row populator circuitry 410 of FIG. 4. The example row populator circuitry 410 includes example multiplexer circuitry 502, example nonlinear (NL) term populator circuitry 506, example multiplexer circuitry 508, and example observation circuitry 512. The example observation circuitry 512 includes subtractor circuitry 518 and multiplexer circuitry 520. Signals used by, generated in, or generated by the row populator circuitry 410 includes an example A(n) signal 504, an example B(n) signal 510, an example selection signal 514, and an example selection signal 516.

The example multiplexer circuitry 502 receives (or retrieves) samples of the digital input x(n) signal 202, the pre-distorted example y(n) signal 204, and the feedback signal z(n) signal 206 from the capture memory 318A. The example multiplexer circuitry 502 also receives the select signal 514, which is generated by the low level controller circuitry 422. The example multiplexer circuitry 502 outputs one of: (1) samples from the x(n) signal 202, (2) samples from y(n) signal 204, or (3) samples from the z(n) signal 206, responsive to the selection signal 514. The output of the example multiplexer circuitry 502 may be referred to as a provided signal or the example A(n) signal 504.

The example NL term populator circuitry 506 populates rows of the H matrix based on the example A(n) signal 504 and stores the rows in the partial H matrix memory 318B. In some examples, the NL term populator circuitry 506 populates one row of NL terms for every one sample in the A(n) signal 504. In other examples, the NL term populator circuitry 506 populates less than one row of NL terms per sample in the A(n) signal 504. The example NL term populator circuitry 506 is described further in connection with FIG. 6B. In some examples, the NL terms are referred to as DPD equation terms.

Like the example multiplexer circuitry 502, the example multiplexer circuitry 508 provides one of: (1) samples from the x(n) signal 202, (2) samples from y(n) signal 204, or (3) samples from the z(n) signal 206, based on instructions from the low level controller circuitry 422. However, the multiplexer circuitry 508 determines which samples to provide based on the selection signal 516, which is separate from the selection signal 514 used by the example multiplexer circuitry 502. The output at the terminal of the example multiplexer circuitry 508 is referred to as the example B(n) signal 510.

The example observation circuitry 512 stores one observation term in the observation memory 318C for each sample of the A(n) signal 504. An observation term is defined as either: 1) a sample of the B(n) signal 510, or 2) the difference between a sample of the B(n) signal 510 and the A(n) signal 504 sample (i.e., B(n)−A(n)). To compute an observation term, the observation circuitry 512 includes subtractor circuitry 518 to compute B(n)−A(n). The observation circuitry 512 also includes multiplexer circuitry 520 to select which input (i.e., A(n) or (B(n)−A(n)) to store in observation memory 318C responsive to both selection signals 514, 516 provided by the low level controller circuitry 422.

The terms stored in observation memory 318C by the observation circuitry 512 may be subsequently used by the row reducer circuitry 414 in reduction operations to determine the H^{H} E matrix from equation (3). The example block diagram of FIG. 5 shows the observation circuitry 512 determining or selecting what value to store using a current sample of the A(n) signal 504. In other examples, the observation circuitry 512 determines or selects what values to store using a previous sample of the A(n) signal 504. Previous samples of the A(n) signal 504 are stored in the NL term memory 318E and are described further in connection with the example A buffer 612 of FIG. 6B.

DPD equations may be implemented in a wide variety of configurations. For example, a first type of DPD equation may cause the DPD corrector circuitry 302 to converge on solved coefficients relatively quickly but generate a relatively large error E in equation (3). Conversely, a second type of DPD equation may cause the DPD corrector circuitry 302 to converge on a solved coefficient relatively slowly but generate a relatively small error E in equation (3). In some examples, the configuration or type of DPD equation implemented is referred to as a learning architecture. In previous solutions, a given DPD circuit may only be able to implement one type of learning architecture, which limits the potential use cases of the DPD circuit.

Advantageously, the example DPD estimator circuitry 316 supports multiple different learning architectures. In a first example, the low level controller circuitry 422 provides the selection signals 514 and 516 such that:
A(n) signal 504=z(n) signal 206,
B(n) signal 510=y(n) signal 204,
and the observation circuitry 512 stores only the B(n) signal 510 in memory 318. Such a first example is an implementation of an indirect learning architecture.

In a second example, the low level controller circuitry 422 provides the selection signals 514 and 516 such that:
A(n) signal 504=x(n) signal 202,
B(n) signal 510=z(n) signal 206,
and the observation circuitry 512 stores B(n)−A(n) in memory 318. Such a second example is an implementation of a direct learning architecture.

In a third example, the low level controller circuitry 422 provides the selection signals 514 and 516 such that:
A(n) signal 504=y(n) signal 204,
B(n) signal 510=z(n) signal 206,
and the observation circuitry 512 stores only the B(n) signal 510 in memory 318. Such a third example is an implementation of a PA model learning architecture.

In some examples, a user or manufacturer may configure the DPD estimator circuitry 316 to use a PA model learning architecture only until a particular implementation of the PA circuitry 210 is sufficiently characterized. In such examples, the user or manufacturer may then re-configure the DPD estimator circuitry 316 to use the direct learning architecture, which may rely on previous PA modeling to increase accuracy. In other examples, a user or manufacturer may configure the DPD estimator circuitry 316 to use the PA model learning architecture without subsequently using the direct learning architecture. In examples where the PA model learning architecture computes a relatively low amount of characterization information (e.g., only a gain term of the PA circuitry), a user or manufacturer may configure the DPD estimator circuitry 316 to only use the direct learning architecture without previously using the PA model learning architecture.

FIG. 6A is a first example block diagram of the memory of FIG. 3. FIG. 6A includes the example NL term memory 318E within the memory 318. The NL term memory 318E includes an example L₁ array 602, an example L₂ array 604, an example L₃ array 606, an example k array 608, an example type array 610, and a basis function memory 611. The example L₁ array 602 includes example terms 602-1, 602-2, . . . , 602-n. The example L₂ array 604 includes example terms 604-1, 604-2, . . . , 604-n. The example L₃ array 606 includes example terms 606-1, 606-2, . . . , 606-n. The example k array 608 includes example terms 608-1, 608-2, . . . , 608-n. The example type array 610 includes example terms 610-1, . . . , 610-n.

The example L₁ array 602, the example L₂ array 604, and the example L₃ array 606 contain lag terms that are pre-determinable based on the type of PA circuitry 210. For example, the terms l_{1,1}(r), l_{2,1}(r), l_{1,2}(r), l_{3,2}(r), l_{2,2}(r), l_{3,3}(r), l_{1,3}(r) and l_{2,3}(r) from equation (1A), are represented within the example L₁ array 602, the example L₂ array 604, and the example L₃ array 606. In particular, each of the example L₁ array 602, the example L₂ array 604, and the example L₃ array 606 may contain as many lag terms as there are terms in a single equation (e.g., 500). The lag terms are used to determine which samples from the A(n) signal 504 are used to form a given DPD equation. In some examples, lag terms are referred to as adjustable lag terms because a user or manufacturer can adjust the lag terms to be any value.

The example type array 610 describes which summation of a DPD equation a particular term belongs to. In particular, a value within the example type array 610 may be implemented as one of three possible values, where a first value corresponds to type-1 (e.g., GMP) terms, a second value corresponds to type-2 terms, and a third value corresponds to type-3 terms as described above. The example k array 608 and the type array 610 are both pre-determinable and have a number of elements equal to the number of terms in a single equation (e.g., 500). As a result, the example L₁ array 602, the example L₂ array 604, the example L₃ array 606, the example k array 608, and the example type array 610 are stored in the memory 318 and received by the example NL term populator circuitry 506 at run time (e.g., when the input x(n) signal 202 is present).

The basis function memory 611 stores high order functions used by the example NL term populator circuitry 506 to generate NL terms. The example basis function memory 611 is described further in connection with FIG. 6B.

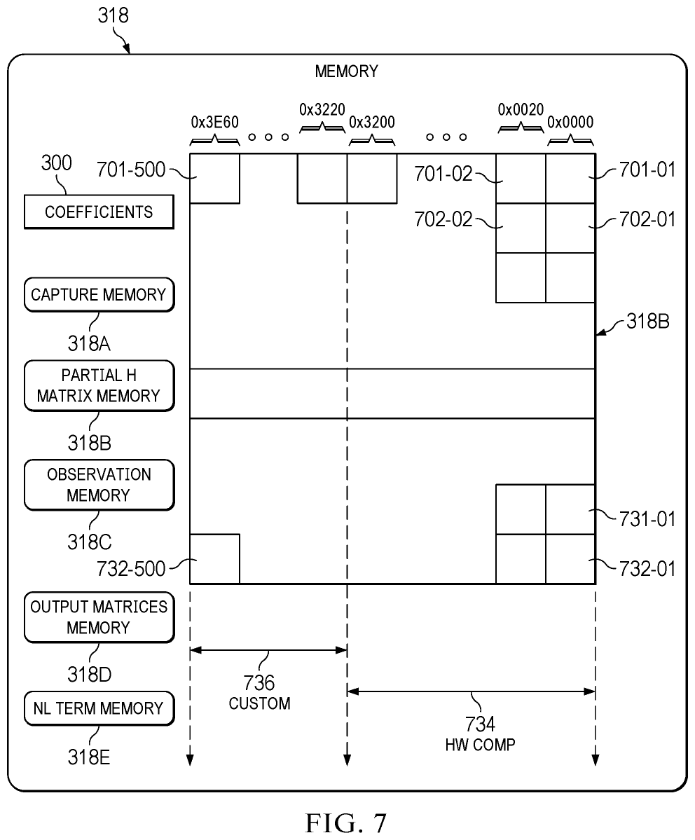

FIG. 6A only illustrates the example NL term memory 318E for simplicity. Additional data structures exist within the example memory 318 as described further in connection with FIGS. 3 and 7.

FIG. 6B is an example block diagram of the NL term populator circuitry 506 of FIG. 5. FIG. 6B includes the example NL term populator circuitry 506, the example L₁ array 602, the example L₂ array 604, the example L₃ array 606, the example k array 608, and the example type array 610. The example NL term populator circuitry 506 includes an example A buffer 612, an example A² buffer 614, an example |A|² buffer 616, an example |A| buffer 618, example multiplexer circuitry 620, example multiplier circuitry 622, the example basis function memory 611, and example multiplier circuitry 626.

The example A buffer 612, the example A² buffer 614, the example |A|² buffer 616, and the example |A| buffer 618 are all first in first out (FIFO) buffers capable of storing the same number of elements. With each sample of the example A(n) signal 504 received from the multiplexer circuitry 502, the example NL term populator circuitry 506 adds a new term and removes the oldest term from each of the foregoing buffers. In particular, the NL term populator circuitry 506 stores one copy of the sample into the example A buffer 612 without modifying the copy. The NL term populator circuitry 506 also squares a second copy of the sample and stores the square of the second copy in the A² buffer 614. The NL term populator circuitry 506 also determines a square of the magnitude of a third copy of the sample, which it then stores in the example |A|² buffer 616. Finally, the NL term populator circuitry 506 determines the magnitude of a fourth copy of the sample, which it then stores in the example |A| buffer 618. Because the x(n) signal 202 is complex, |A(n)|=\sqrt{A(n)_{imag}²+A(n)ᵣₑₐₗ²}. As a result, the A² buffer 614 contains complex terms, and the example |A|² buffer 616 contains real terms.

By adding a new term and removing the oldest term from the foregoing buffers with each new sample, the terms in the example A² buffer 614, the example |A|² buffer 616, and the example |A| buffer 618 correspond to samples that have a range of lags relative to the current sample of the A(n) signal 504. Before a sample of the A(n) signal 504 can be used to generate NL terms, the example NL term populator circuitry 506 may use a number of samples to populate the example A² buffer 614, the example |A|² buffer 616, and the example |A| buffer 618 from an initial empty state.

After adding a new value and removing the oldest value, each of the foregoing buffers outputs a copy of one value within their respective buffer. In the example A buffer 612, the index of the selected value is determined by one of the terms in the L₁ array 602. For example, if term 602-1 is the selected element for the current sample of the A(n) signal 504, the value of term 602-1 (i.e., a lag term) describes which index is selected from the example A buffer 612 to generate the current NL term. Similarly, the index of the selected value from both the example A² buffer 614 and the example |A|² buffer 616 is determined by the corresponding term in the L₃ array 606 (e.g., 606-1). Also, the index of the selected value from the example |A| buffer 618 is determined by a corresponding term in the L₂ array 604 (e.g., 604-1).

The example multiplier circuitry 622 multiplies the output of the A buffer 612 with the output of the multiplexer circuitry 620. The output at the terminal of the A buffer 612 may be characterized as A(n−L₁) or conj[A(n−L₁)], depending on which of the three summations of equation (1A) the current NL term is part of. The example multiplexer circuitry 620, in turn, uses one of the terms in the type array 610 to determine whether to provide the output at the terminal of the example A² buffer 614, the example |A|² buffer 616, or the value ‘1’ to the multiplier circuitry 622.

The example NL term populator circuitry 506 uses the output at the terminal of the example |A| buffer 618 to evaluate a function that is stored in the basis function memory 611. The example basis function memory 611 stores high order functions that describe how the output at the terminal of the example |A| buffer 618 may be used within the DPD equation. For each term within a DPD equation formed, the NL term populator circuitry 506 selects a function from the basis function memory 611 based on the corresponding term in the k array 608. The example NL term populator circuitry 506 then uses the output at the terminal of the example |A| buffer 618 as an input to evaluate the selected function. Finally, the example multiplier circuitry 626 multiplies the output of the selected function with the output at the terminal of the multiplier circuitry 622 and stores the results in the partial H matrix memory 318B. In some examples, the multiplier circuitry 622 and the multiplier circuitry 626 are used to both 1) compute the NL terms as described above, and 2) perform the necessary operations to update the example A buffer 612, the example A² buffer 614, the example |A|² buffer 616, and the example |A| buffer 618.

On average, the example row populator circuitry 410 generates one term of one row stored within the partial H matrix memory 318B per clock cycle. As used above and herein, a clock cycle refers to an amount of time between two pulses of an oscillator (e.g., a clock circuit). The smallest unit of activity by programmable circuitry occurs during a period of one clock cycle. To generate one term within an average of one clock cycle, the example row populator circuitry 410 uses the operations described above.

Advantageously, the example row populator circuitry 410 runs for num_term consecutive clock cycles without changing values in the example A buffer 612, the example A² buffer 614, the example |A|² buffer 616, and the example |A| buffer 618. As used above and herein, num_term is the number of terms generated by the example row populator circuitry 410 in a single DPD equation. For example, in the hypothetical full H matrix with dimensions 20,000×500 described above, num_term≤500. Examples where num_term≤500 are described further below in connection with FIG. 7. After num_term clock cycles, the row populator circuitry 506 removes the oldest value out of each buffer, adds a new value using the foregoing techniques, and begins computing NL terms for the next DPD equation corresponding to a next sample.

Advantageously, the example DPD estimator circuitry 316 supports an adjustable basis function memory 611. As a result, the basis function memory 611 can store different types of high order math functions, and a user or manufacturer can adjust the k array 608 to select a function that best fits a particular use case. Example high order math functions that may be stored in basis function memory 611 may include, but are not limited to, Zernike polynomials, Legendre polynomials, etc.

FIG. 7 is an example block diagram of the memory 318 of FIG. 3. The example memory 318 includes the example DPD coefficients 300, the example capture memory 318A, an example implementation of the partial H matrix memory 318B, the output matrices memory 318D, the example observation memory 318C, and the example NL term memory 318E. Within the memory 318, the partial H matrix memory 318B includes example elements 701-01, 701-02, . . . , 701-500, 702-01, 702-02, . . . , 702-500, . . . , 732-01, 732-02, . . . , 732-500. The example elements can be categorized into an example HW computation section 734 and an example custom section 736.

The example of FIG. 7 shows an implementation of the partial H matrix memory 318B. In the example of FIG. 7, P=32, and each equation contains 500 terms, for simplicity. Furthermore, each column of the matrix in FIG. 7 represents 32 addresses, where one address stores one element of the matrix (i.e., one NL term), for simplicity. In other examples where: 1) the value of P, 2) the number of terms in a DPD equation, or 3) the number of bits in an NL term are different, the partial H matrix memory 318B would have different dimensions.

Advantageously, the example DPD estimator circuitry 316 supports the formation of DPD equations using custom terms. A user or manufacturer may adjust the example high level controller circuitry 420 to add custom terms to implement an equation with custom terms (e.g., an equation that has a different structure than equation (1)). For example, the custom terms are used to implement a fourth or fifth summation, as opposed to the three summations presented in equation (1A). In the example of FIG. 7, num_term=400. That is, each DPD equation includes 400 terms generated by the example NL term populator circuitry 506, which may be used to implement the three summations of equation (1A). Each equation in the example FIG. 7 also includes 100 custom terms. In some other examples, the partial H matrix memory 318B does not contain any custom terms. In still other examples, the partial H matrix memory 318B contains only custom terms.

In the example of FIG. 7, one row of the example partial H matrix memory 318B constitutes or corresponds to one equation corresponding to the state of the A(n) signal 504 from one time instance. For example, elements 701-01, 701-02, . . . , 701-500 correspond to a first DPD equation while elements 702-01, 702-02, . . . , 702-500 correspond to a second DPD equation. As a result, consecutive terms of a DPD equation are not stored in a continuous section of memory addresses. Rather, element 701-01 is stored at address 0x0000, element 701-02 is stored at address 0x00020, . . . , and element 732-500 is stored at 0x3E7F (because 32_{decimal}×500_{decimal}=3E80_{hexadecimal} and 0x3E80−0x0001=0x3E7F). Once the example NL term populator circuitry 506 finishes generating the first set of num_term terms, a new sample of A(n) signal 504 is taken and used to update the example A buffer 612, the example A² buffer 614, the example |A|² buffer 616, and the example |A| buffer 618. The example NL term populator circuitry 506 then generates element 702-01 and stores it at 0x0001, generates element 702-02 and stores it at 0x0021, etc.

In the example of FIG. 7, the custom terms are stored in consecutive memory addresses in the custom section 736, while terms that are generated by the example row populator circuitry 410 are referred to in FIG. 7 as the HW computation section 734. Once the HW computation section 734 has been filled with terms, the high level controller circuitry 420 temporarily disables the low level controller circuitry 422 and performs computations to populate the custom section 736. The computations used to populate custom section 736 are based on the lag terms but do not correspond to a pre-determinable equation type. Once the example custom section 736 is populated, the high level controller circuitry 420 re-enables the low level controller circuitry 422. Upon re-enable, the example low level controller circuitry 422 determines that all P rows of the partial H matrix memory 318B are filled (e.g., in FIG. 7, the filled matrix would be 500 computed terms for each of the 32 DPD equations) and subsequently triggers the row reducer circuitry 414. In some examples, terms in the HW computation section 734 of the partial H matrix memory 318B are referred to as automated equation terms.

FIG. 8 is an example block diagram of the row reducer circuitry 414 of FIG. 4. The example row reducer circuitry includes example cumulative adder structures 802A, 802B, example accumulator circuitry 804A, 804B, example even H^{H} H memory 806A, 806B, example odd H^{H} H memory 808A, 808B, and example multiplexer circuitry 810A, 810B. The example cumulative adder structure 802A includes multiplier circuitries 812A and adder circuitry 814A. Similarly, the example cumulative adder structure 802B includes multiplier circuitries 812B and adder circuitry 814B.

In some configurations, the computation of H^{H} H can be computationally expensive. For example, a H^{H} H computation on a single row of the partial H matrix memory 318B would have a time complexity of O(n²). However, a H^{H} H operation can be decomposed into equation (4):

H^{H}H=Σₙ(hₕ^{H}hₙ). (4)

In equation (4), hₙ refers to an nth DPD equation. Equation (4) can be further decomposed into equation (5):

hₙ^{H}hₙ=[N×1][1×N]. (5)

In equation (5), N refers to the total number of terms in the DPD equation (e.g., 500). Equation (5) indicates that hₙ^{H} is a [N×1] sized matrix that, when multiplied by hₙ, a [1×N] sized matrix, a [N×N] sized matrix is formed. The computation of any arbitrary element in the ith row and jth column of the [N×N] matrix is given by equation (6):

hₙ^{H}hₙ[i,j]=conj(hₙ[i])×hₙ[j]. (6)

In equation (6), conj(hₙ[i]) is the complex conjugate of the ith term in the nth DPD equation.

The example cumulative adder structures 802A, 802B compute versions of the H^{H} H matrix by implementing equation (6) and equation (4) together. In particular, the cumulative adder structure 802A includes P (e.g., 32) multiplier circuitries 812A. Each of the P multiplier circuitries 812A access values from the partial H matrix memory 318B and implement equation (6) in parallel with the other multipliers.

For example, FIG. 8 shows which elements would be multiplied in a first clock cycle of a first iteration to populate the H^{H} H matrix. The first iteration refers to the set of operations performed to populate the first row of the H^{H} H matrix. In the first clock cycle of the first iteration, the first multiplier of the cumulative adder structure 802A multiplies a first pair of elements corresponding to a first equation (e.g., the complex conjugate of element 701-01 is multiplied by the same element 701-01). At the same time (in parallel), the second multiplier in the cumulative adder structure 802A multiplies a second pair of elements corresponding to a second equation (e.g., the complex conjugate of element 702-01 is multiplied with the same element 702-01), etc.

Also, during the first clock cycle of the first iteration, the cumulative adder structure 802B multiplies elements of column 0x0020 of FIG. 7 with elements of the column 0x000 of FIG. 7. That is, the first multiplier in the cumulative adder structure 802B multiplies a third pair of elements corresponding to the first equation (e.g., the complex conjugate of element 701-01 with element 701-02); the second multiplier in the cumulative adder structure 802B multiplies a fourth pair of elements from corresponding to the second equation (e.g., the complex conjugate of element 702-01 with element 702-02); etc. Between both the cumulative adder structure 802A and 802B, a total of 2P products are determined within the first clock cycle of the first iteration. All of the 2P products generated during the first clock cycle of the first iteration correspond to two elements within the first row of the H^{H} H matrix.

In the second clock cycle of the first iteration, the cumulative adder structures 802A, 802B continue to determine products that are used to determine an element in the first row of the H^{H} H matrix. For example, in the second clock cycle of the first iteration, the cumulative adder structure 802A multiplies the complex conjugate of elements of the column 0x000 of FIG. 7 with elements of column 0x0040 of FIG. 7. Similarly, in the second clock cycle of the first iteration, the cumulative adder structure 802B multiplies the complex conjugate of elements of the column 0x000 of FIG. 7 with elements of column 0x0060 of FIG. 7. During the first iteration, the example row reducer circuitry 414 repeats the foregoing pattern in subsequent clock cycles until the complex conjugate of elements of the column 0x000 of FIG. 7 have been multiplied with elements from each of the 500 columns of FIG. 7.

Advantageously, the H^{H} H matrix is a Hermitian matrix, which is a complete square matrix that has repeating elements. Therefore, in order to compute a full row of the H^{H} H matrix, the cumulative adder structures 802A and 802B only needs to repeat the foregoing operations for a portion of the total number of terms in a DPD equation. The symmetry allows the results from any one iteration of the cumulative adder structure 802A to populate two indices of the H^{H} H matrix, except when computing a diagonal entry of the H^{H} H matrix. In other words, only one term out of every two non-diagonal terms is computed by the row reducer circuitry 414 because the second non-diagonal term is a conjugate of the first non-diagonal term. For example, while the first iteration of operations included the multiplication of columns [0x0000-0xE360] to column 0x0000, the second iteration of operations only includes the multiplication of columns [0x0020-0xE360] to columns 0x0020, the third iterations of operations only includes the multiplication of columns [0x0040-0xE360] to columns 0x0040, etc.

After a given clock cycle where the P multiplier circuitries 812A perform parallel computations of one product from P different DPD equations (i.e., P different rows), the adder circuitry 814A implements equation (4) by adding the P products together in the subsequent clock cycle. In particular, the P products added by the adder circuitry 814A correspond to one pair of columns. For example, in the first clock cycle of the first iteration, the pair of columns are the complex conjugate of column 0x0000 and column 0x0000. In the second clock cycle of the first iteration, the pair of columns are the complex conjugate of column 0x0000 and column 0x0040. The resulting sum is one version of one element in the H^{H} H matrix (i.e., one version of H^{H} H[i, j]).

The example adder circuitry 814A provides the copy of H^{H} H[i, j] to the accumulator circuitry 804A, which adds the copy to the pre-existing value of H^{H} H[i, j] within the output matrices memory 318D. For example, the accumulator circuitry 804A first reads the pre-existing value of H^{H} H[i, j] from the H^{H} H memory 318C, then adds the copy of H^{H} H[i, j] term from the adder circuitry 814A, and finally stores the new sum back into the output matrices memory 318D. If the H^{H} H matrix within the output matrices memory 318D was a single section with a single input/output (I/O) port, the update of any given H^{H} H[i, j] element would occur over two clock cycles—one for the read operation, and one for the sum and write operations. In some examples, an I/O port is referred to as an I/O terminal

Advantageously, the example DPD estimator circuitry splits the H^{H} H matrix within the output matrices memory 318C into multiple sections. For example, each of the even H^{H} H memory 806A, 806B, and the odd H^{H} H memory 808A, 808B, are separate sections of the output matrices memory 318C that include a unique I/O port. As a result, the updating of H^{H} H[i, j] elements can be pipelined to achieve a throughput of one update per clock cycle. For example, in a first clock cycle, the accumulator circuitry 804A performs a read operation on the even H^{H} H memory 806A while performing a write operation on the odd H^{H} H memory 808A to update an element of the output matrices memory 318C from an odd-numbered row. In the subsequent second clock cycle, the accumulator circuitry 804A performs a read operation on the odd H^{H} H memory 808A while performing sum and write operations to update an element of the output matrices memory 318D from an even-numbered row. The example multiplexer circuitry 810A facilitates the foregoing operation by receiving the results of read operations and providing the pre-existing value of H^{H} H[i, j] at each clock cycle.

Even with multiplying P terms in parallel with the cumulative adder structure 802A, and with leveraging the symmetry of the H^{H} H matrix to skip the computation of certain elements, the computation of individual H^{H} H matrix versions dominates the overall compute time used to determine the finalized H^{H} H matrix. To reduce the compute time, P can be increased so that the accumulator circuitry 804A performs fewer updates to the H^{H} H matrix within the output matrices memory 318C. However, increasing P also increases the size of the partial H matrix memory 318B and increases the hardware complexity (e.g., more multipliers circuitries 812A would be needed to serve as inputs to the same adder circuitry 814A).

To mitigate the need to increase P, the example row reducer circuitry 414 can be implemented with multiple cumulative adder structures 802A, 802B, multiple accumulator circuitries 804A, 804B, etc. With this implementation of the row reducer circuitry 414, each cumulative adder structure and corresponding circuitry operates on a different subset of the partial H matrix memory 318B. For example, with two cumulative adder structures as shown in FIG. 8, the partial H matrix memory 318B is split into two halves. The two halves may be implemented by any equally sized set of partial H matrix memory 318B columns. In one example, the first half stores even columns while the other half stores odd columns. In other examples, the first half stores columns

$$[ 0 , \frac{n}{2} - 1 ]$$

while the second nan stores rows

$$[ \frac{n}{2} , n - 1 ]$$

(where n is the number of terms in a DPD equation e.g., 500).

By implementing two multiple cumulative adder structures 802A, 802B, the example row reducer circuitry 414 of FIG. 8 generates a total of 2P products per clock cycle instead of P products per cycle achievable with a single cumulative adder structure. In other examples, the row reducer circuitry 414 has a greater number of cumulative adder structures. In such an example, the partial H matrix memory 318B would be subdivided into the greater number of portions.

The example row reducer circuitry 414 can use the foregoing structure and operations to compute both the H^{H} H matrix and the H^{H} E matrix. When computing the H^{H} E matrix, the multiplier circuitries 812A multiply a term from a DPD equation with the corresponding observation term stored in the observation memory 318C by the observation circuitry 512. In some examples, a value stored within the H^{H} E matrix (i.e., a product of a term from the DPD equation and the observation term) is referred to as an error term. Throughout an iteration (i.e., a set of operations used to populate the first row of the H^{H} H matrix as described above), a given multiplier from the multiplier circuitries 812A generates multiple versions of an error term by multiplying the same observation term sampled at a given sample SI with multiple elements from the DPD equation that also corresponds to the sample SI. Accordingly, the computation of one or more error terms in the H^{H} E matrix may be referred to as the reduction of observation terms onto a vector (i.e., the H^{H} E matrix with a dimension of length 1). The H^{H} E matrix is stored within the example output matrices memory 318D as described above.

While an example manner of implementing the DPD estimator circuitry 316 of FIG. 3 is illustrated in FIG. 4, one or more of the elements, processes, and/or devices illustrated in FIG. 4 may be combined, divided, re-arranged, omitted, eliminated, and/or implemented in any other way. Further, the example capture circuitry 402, the example row populator circuitry 410, the example row reducer circuitry 414, the regularization circuitry 418, and/or, more generally, the example DPD estimator circuitry 316 of FIG. 3, may be implemented by hardware alone or by hardware in combination with software and/or firmware. Thus, for example, any of the example capture engine circuitry 402, the example row populator circuitry 410, the example row reducer circuitry 414, the regularization circuitry 418, and/or, more generally, the example DPD estimator circuitry 316 of FIG. 3, could be implemented by processor circuitry, analog circuit(s), digital circuit(s), logic circuit(s), programmable processor(s), programmable microcontroller(s), graphics processing unit(s) (GPU(s)), digital signal processor(s) (DSP(s)), application specific integrated circuit(s) (ASIC(s)), programmable logic device(s) (PLD(s)), and/or field programmable logic device(s) (FPLD(s)) such as Field Programmable Gate Arrays (FPGAs). Further still, the example DPD estimator circuitry 316 of FIG. 3 may include one or more elements, processes, and/or devices in addition to, or instead of, those illustrated in FIG. 4, and/or may include more than one of any or all of the illustrated elements, processes and devices.

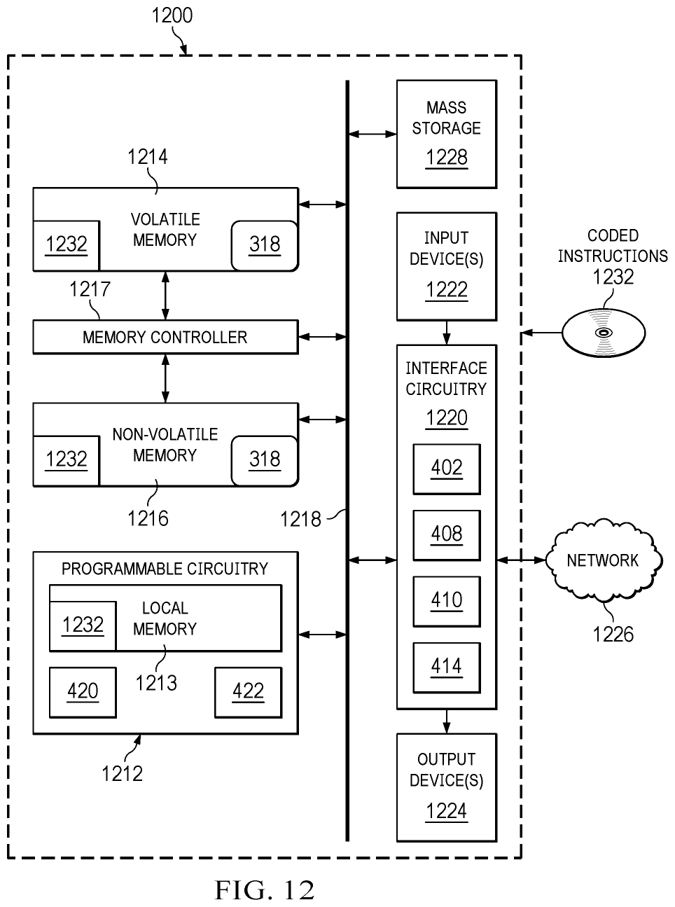

A flowchart representative of example machine-readable instructions, which may be executed to configure processor circuitry to implement the DPD estimator circuitry 316 of FIG. 3, is shown in FIGS. 9-11. The machine-readable instructions may be one or more executable programs or portion(s) of an executable program for execution by processor circuitry, such as the programmable circuitry 1212 shown in the example programmable circuitry platform 1200 described below in connection with FIG. 12. The program may be embodied in software stored on one or more non-transitory computer readable storage media such as a compact disk (CD), a floppy disk, a hard disk drive (HDD), a solid-state drive (SSD), a digital versatile disk (DVD), a Blu-ray disk, a volatile memory (e.g., Random Access Memory (RAM) of any type, etc.), or a non-volatile memory (e.g., electrically erasable programmable read-only memory (EEPROM), FLASH memory, an HDD, an SSD, etc.) associated with processor circuitry located in one or more hardware devices, but the entire program and/or parts thereof could alternatively be executed by one or more hardware devices other than the processor circuitry and/or embodied in firmware or dedicated hardware.

The machine-readable instructions may be distributed across multiple hardware devices and/or executed by two or more hardware devices (e.g., a server and a client hardware device). For example, the client hardware device may be implemented by an endpoint client hardware device (e.g., a hardware device associated with a user) or an intermediate client hardware device (e.g., a radio access network (RAN)) gateway that may facilitate communication between a server and an endpoint client hardware device). Similarly, the non-transitory computer readable storage media may include one or more mediums located in one or more hardware devices.

Further, although the example program is described with reference to the flowchart illustrated in FIGS. 9-11, many other methods of implementing the example DPD estimator circuitry 316 may alternatively be used. For example, the order of execution of the blocks may be changed, and/or some of the blocks described may be changed, eliminated, or combined. Additionally or alternatively, any or all of the blocks may be implemented by one or more hardware circuits (e.g., processor circuitry, discrete and/or integrated analog and/or digital circuitry, an FPGA, an ASIC, a comparator, an operational-amplifier (op-amp), a logic circuit, etc.) structured to perform the corresponding operation without executing software or firmware. The processor circuitry may be distributed in different network locations and/or local to one or more hardware devices (e.g., a single-core processor (e.g., a single core central processor unit (CPU))), a multi-core processor (e.g., a multi-core CPU, an XPU, etc.) in a single machine, multiple processors distributed across multiple servers of a server rack, multiple processors distributed across one or more server racks, a CPU and/or a FPGA located in the same package (e.g., the same integrated circuit (IC) package or in two or more separate housings, etc.).

The machine-readable instructions described herein may be stored in one or more of a compressed format, an encrypted format, a fragmented format, a compiled format, an executable format, a packaged format, etc. Machine-readable instructions as described herein may be stored as data or a data structure (e.g., as portions of instructions, code, representations of code, etc.) that may be utilized to create, manufacture, and/or generate machine executable instructions. For example, the machine-readable instructions may be fragmented and stored on one or more storage devices and/or computing devices (e.g., servers) located at the same or different locations of a network or collection of networks (e.g., in the cloud, in edge devices, etc.). The machine-readable instructions may require one or more of installation, modification, adaptation, updating, combining, supplementing, configuring, decryption, decompression, unpacking, distribution, reassignment, compilation, etc., so that the machine-readable instructions are directly readable, interpretable, and/or executable by a computing device and/or other machine. For example, the machine-readable instructions may be stored in multiple parts, which are individually compressed, encrypted, and/or stored on separate computing devices, wherein the parts when decrypted, decompressed, and/or combined form a set of machine executable instructions that implement one or more operations that may together form a program such as that described herein.

In another example, the machine-readable instructions may be stored in a state in which they may be read by processor circuitry, but require addition of a library (e.g., a dynamic link library (DLL)), a software development kit (SDK), an application programming interface (API), etc., in order to execute the machine-readable instructions on a particular computing device or other device. In another example, the machine-readable instructions may need to be configured (e.g., settings stored, data input, network addresses recorded, etc.) before the machine-readable instructions and/or the corresponding program(s) can be executed in whole or in part. Thus, machine-readable media, as used herein, may include machine-readable instructions and/or program(s) regardless of the particular format or state of the machine-readable instructions and/or program(s) when stored or otherwise at rest or in transit.

The machine-readable instructions described herein can be represented by any past, present, or future instruction language, scripting language, programming language, etc. For example, the machine-readable instructions may be represented using any of the following languages: C, C++, Java, C#, Perl, Python, JavaScript, HyperText Markup Language (HTML), Structured Query Language (SQL), Swift, etc.

As mentioned above, the example operations of FIGS. 9-11 may be implemented using executable instructions (e.g., computer and/or machine-readable instructions) stored on one or more non-transitory computer and/or machine-readable media such as optical storage devices, magnetic storage devices, an HDD, a flash memory, a read-only memory (ROM), a CD, a DVD, a cache, a RAM of any type, a register, and/or any other storage device or storage disk in which information is stored for any duration (e.g., for extended time periods, permanently, for brief instances, for temporarily buffering, and/or for caching of the information). As used herein, the terms non-transitory computer readable medium, non-transitory computer readable storage medium, non-transitory machine-readable medium, and non-transitory machine-readable storage medium are expressly defined to include any type of computer readable storage device and/or storage disk and to exclude propagating signals and to exclude transmission media. As used herein, the terms “computer readable storage device” and “machine-readable storage device” are defined to include any physical (mechanical and/or electrical) structure to store information, but to exclude propagating signals and to exclude transmission media. Examples of computer readable storage devices and machine-readable storage devices include random access memory of any type, read only memory of any type, solid state memory, flash memory, optical discs, magnetic disks, disk drives, and/or redundant array of independent disks (RAID) systems. As used herein, the term “device” refers to physical structure such as mechanical and/or electrical equipment, hardware, and/or circuitry that may or may not be configured by computer readable instructions, machine-readable instructions, etc., and/or manufactured to execute computer readable instructions, machine-readable instructions, etc.

FIG. 9 is a flowchart representative of a first example process that may be performed using machine-readable instructions that can be executed and/or hardware configured to implement the DPD estimator circuitry of FIG. 3, and/or, more generally, the DPD circuitry of FIG. 2 to determine a change to the DPD coefficients. The operations 900 begin when the example capture circuitry 402 receives the DPD input x(n) signal 202, the DPD output y(n) signal 204, and the PA feedback z(n) signal 206. (Block 902). The example capture circuitry 402 receives the input x(n) signal 202 from the processor circuitry 106A, the y(n) signal 204 from the DPD corrector circuitry 302, and the z(n) signal 206 from the FB digital circuitry 314. The example high level controller circuitry 420 also controls the capture circuitry 402 to sample the received signals at block 902.

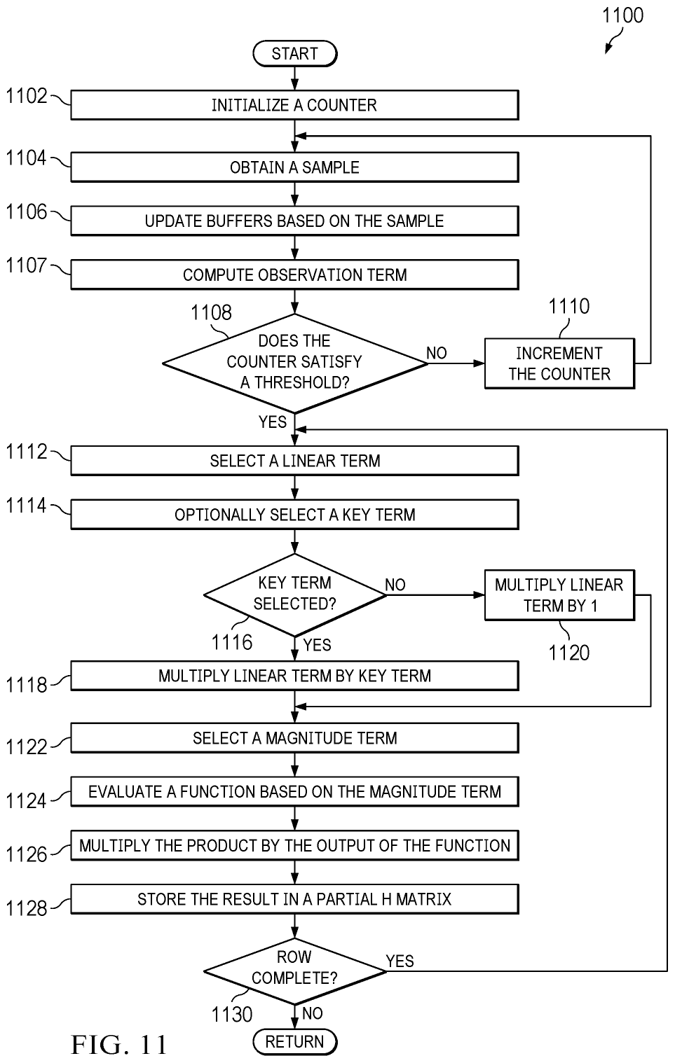

The example row populator circuitry 410 uses the sampled signals to populate a row of the partial H matrix memory 318B. (Block 904). A row of the partial H matrix memory 318B corresponds to one DPD equation and one point in time (e.g., one clock cycle). The example row populator circuitry 410 populates, at most, one row of the partial H matrix memory 318B per one set of samples (e.g., one sample of the x(n) signal 202, one sample of the y(n) signal 204, and one sample of the z(n) signal 206 that all correspond to the same point in time). Block 904 is described further in FIG. 11.

The example low level controller circuitry 422 checks whether a threshold number, P. of rows are in the partial H matrix memory 318B. (Block 906). If P rows are not present in the partial H matrix memory 318B (block 906: No), control returns to block 904, where the example row populator circuitry 410 populates an additional row of the partial H matrix memory 318B using an additional set of samples.

If P rows are present in the partial H matrix memory 318B (block 906: Yes), the example low level controller circuitry 422 triggers the row reducer circuitry 414 to reduce and accumulate the contents of the partial H matrix memory 318B into the example H^{H} H matrix within the output matrices memory 318C. (Block 908). To reduce the contents of the partial H matrix memory 318B, the example row reducer circuitry 414 includes a cumulative adder structure 802A to implement equation (6) for one term of P different DPD equations in parallel. The example row reducer circuitry 414 may partition the example output matrices memory 318D and/or the example partial H matrix memory 318B into multiple portions to increase the throughput of H^{H} H term generation and mitigate the need to increase P, as described previously in FIG. 8.

The example row reducer circuitry 414 also stores error terms within the H^{H} E matrix of the output matrices memory 318D at block 908. To generate a given error term, the row reducer circuitry 414 iteratively multiplies terms of a DPD equation with a corresponding observation term as described above in connection with FIG. 8.

The example high level controller circuitry 420 determines whether the row reducer circuitry 414 has performed a threshold number of reduction operations. (Block 910). In some examples, the threshold of block 910 is based on a total number of samples that are desired for use in determining Δcₖ in equation (3). For example, in the previous hypothetical where the capture circuitry 402 records approximately 20,000 samples before providing the H^{H} H and H^{H} E matrices to the CG solver circuitry 408, the threshold of block 914 may be approximately equal to

$$\frac{20 , 000}{P} .$$

If the high level controller circuitry 420 determines that row reducer circuitry 414 has not performed the threshold number of reduction operations (Block 910: No), control returns to block 904 where the example row populator circuitry 410 populates an additional row of the partial H matrix memory 318B using an additional set of samples. Alternatively, if the high level controller circuitry 420 determines the row reducer circuitry 414 has performed a threshold number of reduction operations (Block 910: Yes), the example high level controller circuitry 420 controls the regularization circuitry 418 to regularize the example H^{H} H matrix within the output matrices memory 318C. (Block 912). In particular, the regularization circuitry 418 can add additive and multiplicative regularization terms to the diagonal entries of the H^{H} H matrix. In some examples, one or more of the regularization terms added to the diagonal entries are unique.

The example high level controller circuitry 420 controls the CG solver circuitry 408 to determine a change to DPD coefficients (e.g., implement equation (3) to determine Δcₖ) based on the regularized H^{H} H matrix and the H^{H} E matrix stored in the output matrices memory 318D. (Block 914). The example CG solver circuitry 408 uses the regularized H^{H} H matrix and the H^{H} E matrix to find Δcₖ as described in U.S. patent application Ser. No. 17/977,813. In turn, the example DPD corrector circuitry 302 uses Δcₖ to modify the coefficients 300 and improve the accuracy of a DPD model. Accordingly, the modification of the coefficients 300 causes more accurate pre-distortions and less error in a received signal (e.g., the signal received by receiver circuitry 110B). For example, a first sample of the pre-distorted y(n) signal 204 that corresponds to the original coefficients 300 values will include more error in a first received signal than a second received signal that corresponds to a second sample of the pre-distorted y(n) signal 204 formed using modified coefficients 300 values.

The example high level controller circuitry 420 determines whether the capture circuitry 402 will receive more samples. (Block 916). If the example high level controller circuitry 420 more samples are to be received (block 916: Yes), control returns to block 902 where the example capture circuitry 402 receives the additional samples of the DPD input x(n) signal 202, the DPD output y(n) signal 204, and the PA feedback z(n) signal 206. Alternatively, if the example high level controller circuitry 420 no more samples are to be received (block 916: No), the example machine-readable instructions and/or operations 900 end.

The example flowchart of FIG. 9 illustrates the threshold of block 910 being satisfied once per loop of blocks 902-916. In other examples, the example DPD estimator circuitry 316 iterates through blocks 902-910 for one or more loops before implementing block 912. For example, suppose the H matrix of equation (3) has 20,0000 rows but the memory 318 is only large enough to store 4,0000 samples of the x(n) signal 202 at a time. In such examples, the DPD estimator circuitry 316 iterates through blocks 902-910 before regularizing the H^{H} H matrix with 20,000 rows.

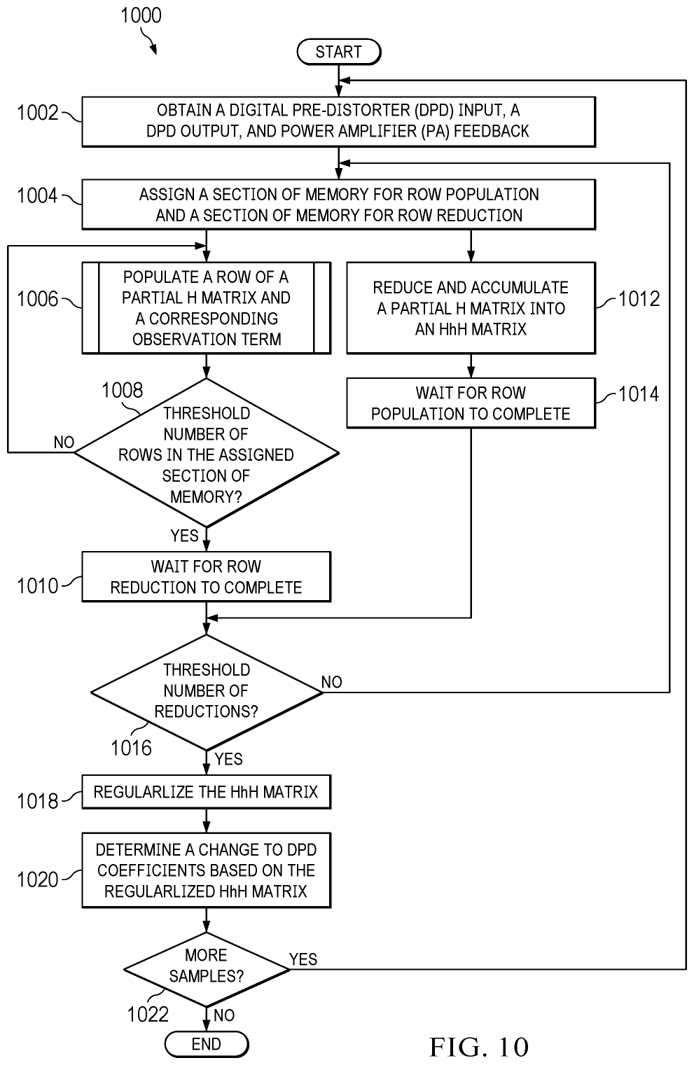

FIG. 10 is a flowchart representative of a second example process that may be performed using machine-readable instructions and/or operations that can be executed and/or hardware configured to implement the DPD estimator circuitry of FIG. 3, and/or, more generally, the DPD circuitry of FIG. 2 to determine a change to the DPD coefficients. The example machine-readable instructions and/or operations 1000 begin when the example capture circuitry 402 receives the DPD input x(n) signal 202, the DPD output y(n) signal 204, and the PA feedback z(n) signal 206. (Block 1002). The example capture circuitry 402 receives the input x(n) signal 202 from the processor circuitry 106A, the y(n) signal 204 from the DPD corrector circuitry 302, and the z(n) signal 206 from the FB digital circuitry 314. The example high level controller circuitry 420 also controls the capture circuitry 402 to sample the received signals at block 1002.

The example low level controller circuitry 422 assigns a section of the memory 318 for row population and a section of the memory 318 for row reduction. (Block 1004). The sections of memory 318 may refer to any set of addresses within the memory 318 and may be any size.

The example row populator circuitry 410 uses the sampled signals to populate a row of the partial H matrix memory 318B. (Block 1006). The example row populator circuitry 410 implements block 1006 of FIG. 10 and block 904 of FIG. 9 in the same manner. Block 904 and block 1006 are described further in FIG. 11.

The example low level controller circuitry 422 checks whether a threshold number, P. of rows are in the partial H matrix memory 318B. (Block 1008). If P rows are not present in the partial H matrix memory 318B (block 1008: No), control returns to block 1006, where the example row populator circuitry 410 uses an additional set of sampled signals to populate an additional row of the partial H matrix memory 318B. If the example low level controller circuitry 422 determines P rows are present in the partial H matrix memory 318B (block 1008: Yes), the example low level controller circuitry 422 optionally controls the row populator circuitry 410 to wait until the row reduction operations of block 1012 are complete. (Block 1010).

While the row populator circuitry 410 implements block 1006, the example row reducer circuitry 414 reduces and accumulates a prior partial H matrix into the example H^{H} H matrix within the output matrices memory 318C. (Block 1012). For example, while the row populator circuitry 410 iterates between block 1006 and block 1008 to generate rows [P+1, 2P] of a hypothetical full H matrix, the row reducer circuitry 414 simultaneously implements block 1012 to reduce and accumulate rows [0, P] of a hypothetical full H matrix. While the example row reducer circuitry 414 does not implement block 1012 during a first implementation of block 1006 and block 1008 (e.g., while the row populator circuitry 410 generates rows [0, P]), the example row reducer circuitry 414 operates in parallel with the row populator circuitry 410 for all subsequent implementations.

The example row reducer circuitry 414 also stores error terms within the H^{H} E matrix of the output matrices memory 318D at block 1012. To generate a given error term, the row reducer circuitry 414 iteratively multiplies terms of a DPD equation with a corresponding observation term as described above in connection with FIG. 8.

The example low level controller circuitry 422 optionally controls the row reducer circuitry 414 to wait for the row populator circuitry 410 to complete a set of P rows. (Block 1014). For any one loop of blocks 1004-1016, only one of the row populator circuitry 410 and the row reducer circuitry 414 will finish their respective operations first. As a result, for each loop of blocks 1004-1016, the example low level controller circuitry 422 implements one of block 1010 or block 1014 and skips the other block. In many examples, row reduction operations dominate compute time, so block 1010 is implemented and block 1014 is skipped.

Once both the row populator circuitry 410 has generated P rows of the hypothetical full H matrix and the row reducer circuitry 414 has reduced and accumulated the previous P rows of the hypothetical full H matrix, the example high level controller circuitry 420 determines whether the row reducer circuitry 414 has performed a threshold number of reduction operations. (Block 1016). In some examples, the threshold of block 1016 and the threshold of block 910 are the same. If the row reducer circuitry 414 has not performed a threshold number of reduction operations (block 1016: No), control returns to block 1004 where the sections of memory are re-assigned. Alternatively, if the row reducer circuitry 414 has performed a threshold number of reduction operations (block 1016: Yes), control proceeds to block 1018.

The example DPD estimator circuitry 316 implements block 1018 and block 1020 of FIG. 10 in the same manner that block 912 and block 914 are implemented in FIG. 9. That is, the example high level controller circuitry 420 controls the regularization circuitry 418 to regularize the example H^{H} H matrix within the output matrices memory 318C (block 1018), and the high level controller circuitry 420 controls the CG solver circuitry 408 to determine a change to DPD coefficients (block 1020).

The example high level controller circuitry 420 determines whether the capture circuitry 402 will receive more samples. (Block 1022). If the example high level controller circuitry 420 determines to receive more samples (Block 1022: Yes), control returns to block 1002 where the example capture circuitry 402 receives the additional samples of the DPD input x(n) signal 202, the DPD output y(n) signal 204, and the PA feedback z(n) signal 206. Alternatively, if the example high level controller circuitry 420 determines not to receive more samples (Block 1022: No), the example machine-readable instructions and/or operations 1000 end.

When assigning sections of memory during a subsequent loop of block 1004, the example low level controller circuitry 422 swaps the memory assignment from the previous loop of block 1004. For example, suppose that during a second loop of block 1004, the low level controller circuitry 422 assigns section A of memory 318 to the row populator circuitry 410 and section B of memory 318 to the row reducer circuitry 414. In such an example, during the third loop of block 1004, the low level controller circuitry 422 then assigns section B of memory 318 to the row populator circuitry 410 and section A of memory 318 to the row reducer circuitry 414. In this manner, during the third loop, the row reducer circuitry 414 can reduce rows [P+1: 2P] of the H matrix that were generated during the second loop. During the third loop, the example row populator circuitry 410 also populates rows [2P+1: 3P] of the H matrix where rows [1: P] were previously stored. Such an overwrite of rows is advantageous because it reduces the total amount of memory 318 used to implement the DPD estimator circuitry 316 while not losing information. Information is not lost during the overwrite of the third loop because the row reducer circuitry 414 has already reduced rows [1: P] and accumulated the result into the example H^{H} H matrix within the output matrices memory 318C (which is in memory 318 but separate from portions A and B) during the second loop.

The example machine-readable instructions and/or operations 900 and the example machine-readable instructions and/or operations 1000 are two alternative methods of implementing the example DPD estimator circuitry 316. The machine-readable instructions and/or operations 900 are an example implementation of a serialized architecture in which a first set of P rows are fully populated, reduced, and accumulated onto the example H^{H} H matrix within the output matrices memory 318C before the row populator circuitry 410 begins to populate a second set of P rows. In contrast, the machine-readable instructions and/or operations 1000 are an example implementation of a parallel architecture in which the population, reduction, and accumulation of a first and second set of P rows are partially overlaid in time through pipelining. The example machine-readable instructions and/or operations 1000 may reduce the compute time of determining Δcₖ from equation (3) relative to the example machine-readable instructions and/or operations 900. To implement such time improvements, the example machine-readable instructions and/or operations 1000 may also require space in an additional integrated circuit (IC) layout and/or a more complex design(s) of the high level controller circuitry 420 and the low level controller circuitry 422.

Advantageously, the example DPD estimator circuitry 316 is adjustable in that a user or manufacturer can choose between a serialized implementation such as FIG. 9 or a parallelized architecture of FIG. 10. In doing so, the example DPD estimator circuitry 316 enables a user or manufacturer to choose how to prioritize compute time with IC space and design complexity to best suit a particular use case.

FIG. 11 is a flowchart representative of an example process that may be performed using machine-readable instructions and/or operations that can be executed and/or hardware configured to populate a row of a partial matrix as described in FIGS. 9 and 10. In particular, the machine-readable instructions and/or operations 1100 are an example implementation of block 904 from FIG. 9 and block 1006 from FIG. 10.

Execution of block 904 and block 1006 begins when the example low level controller circuitry 422 initializes a counter. (Block 1102). The example NL term populator circuitry 506 then receives a sample of the A(n) signal 504 from the multiplexer circuitry 502. (Block 1104). The sample of the A(n) signal 504 refers to a sample from one of either the x(n) signal 202, the y(n) signal 204, or the z(n) signal 206. The contents of the A(n) signal 504 and the sample of block 1104 are determined by the low level controller circuitry 422 via the selection signal 514.

The example NL term populator circuitry 506 updates the example A buffer 612, the example A² buffer 614, the example |A|² buffer 616, and the example |A| buffer 618 based on the sample of block 1104. (Block 1106). That is, the NL term populator circuitry 506 performs mathematical operations on four copies of the sample to form a linear term (x), two key terms (A² and |A|²), and a basis function selector term (|x|). The NL term populator circuitry 506 then adds the new terms to their respective buffers and removes the oldest entry from each of the buffers, as described previously in connection with FIG. 6B.

The example observation circuitry 512 computes an observation term needed to form the H^{H} E matrix. (Block 1107). The example observation circuitry 512 computes the observation term as described above in connection with FIG. 5. During each subsequent loop of blocks 1104-1110, the example observation circuitry 512 computes a new observation term based on the received sample of block 1104 and overwrites the old observation term from the previous loop. As a result, only one observation term is stored in the output matrices memory 318D for a given DPD equation at any point in time. Additionally, the one observation term stored in the H^{H} E matrix for the given DPD equation is determined by the implementing the last loop of blocks 1104-1110 before control proceeds to block 1112.

The example low level controller circuitry 422 determines whether the counter satisfies a threshold. (Block 1108). The threshold of block 1108 may be satisfied when the counter is greater or equal to a pre-determined value. The threshold value of block 1108 may be any number. The threshold value may be based on the sample rate of the example capture circuitry 402 and the use case of the DPD estimator circuitry 316.

If the counter does not satisfy the threshold (Block 1108: No), the example low level controller circuitry 422 increments the counter. (Block 1110). Control then returns to block 1104, where the example NL term populator circuitry 506 receives a new sample of the A(n) signal 504.

If the counter does satisfy the threshold (Block 1108: Yes), the example NL term populator circuitry 506 selects a linear term. (Block 1112). In particular, the example NL term populator circuitry 506 chooses a value from the example A buffer 612 based on one of the terms in the example L₁ array 602 (e.g., term 602-1) as described in connection with FIG. 6B.

The example NL term populator circuitry 506 optionally selects a key term. (Block 1114). In particular, the example NL term populator circuitry 506 may, in some examples, select either: 1) a value from the example A² buffer 614, or 2) a value from the example |A|² buffer 616, based on one of the terms in the example L₃ array 606 (e.g., term 606-1). The example NL term populator circuitry 506 determines which key term to select, if any, based on a term in the example type array 610.

The example NL term populator circuitry 506 determines whether a key term is selected. (Block 1116). If a key term is selected (block 1116: Yes), the example NL term populator circuitry 506 multiplies the linear term with the selected key term. (Block 1118). Alternatively, if a key term is not selected (block 1116: No), the example NL term populator circuitry 506 multiplies the linear term by 1. (Block 1120). Control proceeds to block 1122 after either block 1118 or block 1120.

The example NL term populator circuitry 506 selects a magnitude term. (Block 1122). In particular, the NL term populator circuitry 506 selects a value from the example |A| buffer 618 based on one of the terms in the example L₂ array 604 (e.g., term 604-1) as described in connection with FIG. 6B.

The example NL term populator circuitry 506 evaluates a function from the basis function memory 611 based on one of the terms in the example k array 608 (e.g., term 608-1) and the selected magnitude term. (Block 1124). To evaluate the function, the NL term populator circuitry 506 uses the selected magnitude term of block 1122 as an input to the function and generates an output as described in connection with FIG. 6B. In FIG. 6B, the example DPD estimator circuitry 316 uses a look up table (LUT) to evaluate the function from the basis function memory 611. In other examples, dedicated hardware may be used to evaluate the function from the basis function memory 611 and implement block 1124.

The example NL term populator circuitry 506 multiplies the product of either block 1118 or block 1120 with the output of the function. (Block 1126). The resulting product is one term of a DPD equation, which the NL term populator circuitry 506 stores in the partial H matrix memory 318B. (Block 1128).

The example low level controller circuitry 422 determines whether the row of the partial H matrix memory 318B that stores the term from block 1128 is now complete. (Block 1130). If the row is not complete (block 1130: No), control returns to block 1112, where the example NL term populator circuitry 506 selects another linear term. If the row is complete (block 1130: yes), control returns to one of either block 906 or block 1008.

In many examples, the compute time used to select values from the buffers of FIG. 6A, evaluate a function stored in the basis function memory 611, and multiply the appropriate terms together largely outweighs the compute time to update the buffers. Furthermore, in some examples, the example capture circuitry 402 samples the x(n) signal 202, the y(n) signal 204, and the z(n) signal 206 more frequently than is needed to determine Δcₖ in equation (3).

Advantageously, FIG. 11 shows how the DPD estimator circuitry 316 supports efficient computation in such examples. In particular, the example NL term populator circuitry 506 only performs the computationally task of implementing blocks 1112 through 1130 for a portion of the samples of A(n) signal 504, thereby decimating equations that could have been formed from other samples. The example NL term populator circuitry 506 does update the buffers for each received sample of the A(n) signal 504 so that the buffers contain the correct lag information when a new DPD term is computed (block 1108: Yes). Furthermore, the DPD estimator circuitry 316 can implement blocks 1112-1130 in a pipeline architecture such that one NL term is computed per clock cycle, even though the pipeline latency (i.e., the number of clock cycles during which one loop of blocks 1112-1130 is implemented) is greater than one clock cycle.

FIG. 12 is a block diagram of an example programmable circuitry platform 1200 structured to execute and/or instantiate the machine-readable instructions and/or the operations of FIGS. 9-11 to implement the DPD estimator circuitry 316 of FIG. 3. The programmable circuitry platform 1200 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, a DVD player, a CD player, a digital video recorder, a Blu-ray player, a gaming console, a personal video recorder, a set top box, a headset (e.g., an augmented reality (AR) headset, a virtual reality (VR) headset, etc.) or other wearable device, or any other type of computing and/or electronic device.

The programmable circuitry platform 1200 of the illustrated example includes programmable circuitry 1212. The programmable circuitry 1212 of the illustrated example is hardware. For example, the programmable circuitry 1212 can be implemented by one or more integrated circuits, logic circuits, FPGAs, microprocessors, CPUs, GPUs, DSPs, and/or microcontrollers from any desired family or manufacturer. The programmable circuitry 1212 may be implemented by one or more semiconductor based (e.g., silicon based) devices. In this example, the programmable circuitry 1212 implements the high level controller circuitry 420 and the low level controller circuitry 422.

The programmable circuitry 1212 of the illustrated example includes a local memory 1213 (e.g., a cache, registers, etc.). The programmable circuitry 1212 of the illustrated example is in communication with a main memory including a volatile memory 1214 and a non-volatile memory 1216 by a bus 1218. The volatile memory 1214 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 1216 may be implemented by flash memory and/or any other desired type of memory device. Access to the main memory 1214, 1216 of the illustrated example is controlled by a memory controller. In this example, one or both of the volatile memory 1214 and the non-volatile memory 1216 implement the memory 318.

Access to the main memory 1214, 1216 of the illustrated example is controlled by a memory controller 1217. In some examples, the memory controller 1217 may be implemented by one or more integrated circuits, logic circuits, microcontrollers from any desired family or manufacturer, or any other type of circuitry to manage the flow of data going to and from the main memory 1214, 1216

The programmable circuitry platform 1200 of the illustrated example also includes interface circuitry 1220. The interface circuitry 1220 may be implemented by hardware utilizing any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface.

In the illustrated example, one or more input devices 1222 are connected to the interface circuitry 1220. The input device(s) 1222 permit(s) a user (e.g., a human user, a machine user, etc.) to enter data and/or commands into the programmable circuitry 1212. The input device(s) 1222 can be implemented by, for example, an audio sensor, a microphone, a camera (still or video), a keyboard, a button, a mouse, a touchscreen, a trackpad, a trackball, and/or a voice recognition system.

One or more output devices 1224 are also connected to the interface circuitry 1220 of the illustrated example. The output device(s) 1224 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 1220 of the illustrated example, thus, includes a graphics driver card, a graphics driver chip, and/or graphics processor circuitry such as a GPU.

The interface circuitry 1220 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 1226. The communication can be by, for example, an Ethernet connection, a digital subscriber line (DSL) connection, a telephone line connection, a coaxial cable system, a satellite system, beyond-line-of-site wireless system, a line-of-site wireless system, a cellular telephone system, an optical connection, etc. In this example, the interface circuitry 1220 implements the capture circuitry 402, the CG solver circuitry 408, the row populator circuitry 410, the row reducer circuitry 414, and the regularization circuitry 418.

The programmable circuitry platform 1200 of the illustrated example also includes one or more mass storage discs or devices 1228 to store software and/or data. Examples of such mass storage devices 1228 include magnetic storage discs or devices, optical storage devices, floppy disk drives, HDDs, CDs, Blu-ray disk drives, redundant array of independent disks (RAID) systems, solid state storage devices such as flash memory devices and/or SSDs, and DVD drives.

The machine-readable instructions 1232, which may be implemented by the machine-readable instructions of FIGS. 9-11, may be stored in the mass storage device 1228, in the volatile memory 1214, in the non-volatile memory 1216, and/or on at least one non-transitory computer readable storage medium such as a CD or DVD which may be removable.

In this description, the term “and/or” (when used in a form such as A, B and/or C) refers to any combination or subset of A, B, C, such as: (a) A alone; (b) B alone; (c) C alone; (d) A with B; (c) A with C; (f) B with C; and (g) A with B and with C. Also, as used herein, the phrase “at least one of A or B” (or “at least one of A and B”) refers to implementations including any of: (a) at least one A; (b) at least one B; and (c) at least one A and at least one B.

Example methods, apparatus and articles of manufacture described herein determine a DPD equation in an adjustable and efficient manner. The example DPD estimator circuitry 316 can generate an equation using a PA modeling, direct learning, or indirect learning architecture. The example equation can be generated with or without custom terms that expand the equation past the three summation architecture of equation (1A). The automatically generated terms may be calculated in either a parallelized or a serial architecture. The example DPD estimator circuitry 316 also minimizes compute time and resource utilization at least by skipping the computation of terms for some high frequency signals, by leveraging the symmetry of the Hermitian matrix to only reduce certain elements of the H^{H} H matrix, and by splitting the output matrices memory 318C into multiple portions to enable simultaneous read and write operations.

Numerical identifiers such as “first”, “second”, etc. are used merely to distinguish between elements of substantially the same type in terms of structure and/or function. Identifiers used in the description do not necessarily align with those used in the claims.

A device that is “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C. (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A. (2) at least one B, or (3) at least one A and at least one B. As used herein in the context of describing the performance or execution of processes, instructions, actions, activities and/or steps, the phrase “at least one of A and B” is intended to refer to implementations including any of (1) at least one A. (2) at least one B, or (3) at least one A and at least one B. Similarly, as used herein in the context of describing the performance or execution of processes, instructions, actions, activities and/or steps, the phrase “at least one of A or B” is intended to refer to implementations including any of (1) at least one A. (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements or method actions may be implemented by, e.g., the same entity or object. Additionally, although individual features may be included in different examples or claims, these may possibly be combined, and the inclusion in different examples or claims does not imply that a combination of features is not feasible and/or advantageous.

Modifications are possible in the described embodiments, and other embodiments are possible, within the scope of the claims.

What is claimed is:

1. An apparatus comprising:
memory storing machine-readable instructions; and
programmable circuitry configured to execute the machine-readable instructions to:
receive an input signal, a digital pre-distorter (DPD) output signal, and a power amplifier (PA) feedback signal;
populate a partial matrix with a threshold number of rows of equation terms based on the input signal, the DPD output signal, and the PA feedback signal;
compute a respective observation term for each row in the threshold number of rows based on the input signal, the DPD output signal, and the PA feedback signal;
reduce the partial matrix into a Hermitian matrix and reduce the observation terms into a vector;
accumulate the Hermitian matrix and the vector onto the memory;
regularize, after a determination that a threshold number of Hermitian matrices have been accumulated, the memory to form an output matrix; and
pre-distort the input signal using the output matrix.

2. The apparatus of claim 1, wherein the machine-readable instructions cause the programmable circuitry to:
use a buffer to determine a first row of equation terms in the partial matrix, the first row corresponding to a first time;
sample a provided signal at a second time;
update the buffer with a second term based on the sample at the second time, the buffer to include a first term and the second term, the first term corresponding to a sample of the provided signal recorded at the first time, the second time occurring after the first time; and
use the buffer to determine a second row of equation terms in the partial matrix, the second row corresponding to a second time.

3. The apparatus of claim 2, wherein:
the provided signal is the PA feedback signal; and
the instructions cause the programmable circuitry to determine DPD coefficients using an indirect learning architecture.

4. The apparatus of claim 2, wherein:
the provided signal is the input signal; and
the machine-readable instructions cause the programmable circuitry to determine a change to DPD coefficients using a direct learning architecture.

5. The apparatus of claim 2, wherein to use the buffer to determine a row of equation terms, the programmable circuitry is to:
select a term from the buffer, the selection based on an index stored in an array of adjustable lag terms; and
determine one term of an equation based on the selected term.

6. The apparatus of claim 5, wherein:
the equation terms are automated equation terms; and
the machine-readable instructions cause the programmable circuitry to:
determine custom equation terms based on the adjustable lag terms; and
populate a portion of the first row of the partial matrix and a portion of the second row of the partial matrix with the custom equation terms.

7. The apparatus of claim 2, wherein the machine-readable instructions cause the programmable circuitry to:
receive a first sample of a provided signal;
perform a first update to the buffer based on the first sample;
receive a second sample of a provided signal;
perform a second update to the buffer based on to the second sample; and
determine one row of equation terms in the partial matrix based on the second update.

8. The apparatus of claim 1, wherein:
even-numbered columns of the partial matrix are stored in a first portion of memory;
odd-numbered columns of the partial matrix are stored in a second portion of memory; and
the machine-readable instructions cause the programmable circuitry to:
update, using two write operations, a first element of the output matrix in the first portion of memory and a second element of the output matrix in the second portion of memory; and
receive, using two read operations, a third element of the output matrix in the first portion of memory and a fourth element of the output matrix in the second portion of memory, wherein the two write operations and the two read operations occur in parallel.

9. The apparatus of claim 1, wherein to reduce the partial matrix, the machine-readable instructions cause the programmable circuitry to:
perform a first multiplication of a first pair of elements from a first row of the partial matrix;
perform a second multiplication of a second pair of elements from a second row of the partial matrix, the second multiplication to occur in parallel with the first multiplication, the first pair of elements and the second pair of elements corresponding to a same pair of columns; and
add a product of the first multiplication to a product of the second multiplication.

10. The apparatus of claim 9, wherein:
the addition is a first addition corresponding to a first pair of columns of the partial matrix; and
the machine-readable instructions cause the programmable circuitry to perform a second addition in parallel with the first addition, the second addition corresponding to a second, different pair of columns of the partial matrix.

11. A method to estimate pre-distortion coefficients, the method comprising:
receiving an input signal, a digital pre-distorter (DPD) output signal, and a power amplifier (PA) feedback signal;
populating a partial matrix with a threshold number of rows of equation terms based on the input signal, the DPD output signal, and the PA feedback signal;
computing a respective observation term for each row in the threshold number of rows based on the input signal, the DPD output signal, and the PA feedback signal;
reducing the partial matrix into a Hermitian matrix and reducing the observation terms into a vector;
accumulating the Hermitian matrix and the vector onto a memory;
regularizing, after a determination that a threshold number of Hermitian matrices have been accumulated, the memory to form an output matrix; and
pre-distorting the input signal using the output matrix.

12. The method of claim 11, further including:
using a buffer to determine a first row of equation terms in the partial matrix, the first row corresponding to a first time;
sampling a provided signal at a second time;
updating the buffer with a second term based on the sample at the second time, the buffer to include a first term and the second term, the first term corresponding to a sample of the provided signal recorded at a first time, the second time occurring after the first time; and
using the buffer to determine a second row of equation terms in the partial matrix, the second row corresponding to a second time.

13. The method of claim 12, wherein:
the provided signal is the PA feedback signal; and
the method further includes determining DPD coefficients using an indirect learning architecture.

14. The method of claim 12, wherein:
the provided signal is the input signal; and
the method further includes determining a change to DPD coefficients using a direct learning architecture.

15. The method of claim 12, wherein:
the equation terms are automated equation terms; and
the method further includes:
determining custom equation terms based on adjustable lag terms; and
populating a portion of the first row of the partial matrix and a portion of the second row of the partial matrix with the custom equation terms.

16. The method of claim 12, further including:
receiving a first sample of a provided signal;
performing a first update to the buffer based on the first sample;
receiving a second sample of a provided signal;
performing a second update to the buffer based on the second sample; and
determining one row of equation terms in the partial matrix based on the second update.

17. The method of claim 11, wherein:
even-numbered columns of the partial matrix are stored in a first portion of memory;
odd-numbered columns of the partial matrix are stored in a second portion of memory; and
the method further includes:
updating, using two write operations, a first element of the output matrix in the first portion of memory and a second element of the output matrix in the second portion of memory; and
receiving, using two read operations, a third element of the output matrix in the first portion of memory and a fourth element of the output matrix in the second portion of memory, wherein the two write operations and the two read operations occur in parallel.

18. The method of claim 11, wherein reducing the partial matrix includes:
performing a first multiplication of a first pair of elements from a first row of the partial matrix;
performing a second multiplication a second pair of elements from a second row of the partial matrix, the second multiplication to occur in parallel with the first multiplication; and
adding a product of the first multiplication to a product of the second multiplication.

19. An apparatus to estimate pre-distortion coefficients, the apparatus comprising:
memory;
machine-readable instructions; and
programmable circuitry to at least one of instantiate or execute the machine-readable instructions to:
receive an input signal, a digital pre-distorter (DPD) output signal, and a power amplifier (PA) feedback signal;
populate a partial matrix with a threshold number of rows of equation terms based on the input signal, the DPD output signal, and the PA feedback signal;
compute a respective observation term for each row in the threshold number of rows based on the input signal, the DPD output signal, and the PA feedback signal;
reduce the partial matrix into a Hermitian matrix and reducing the observation terms into a vector;
accumulate the Hermitian matrix and the vector onto a memory;
regularize, after a determination that a threshold number of Hermitian matrices have been accumulated, the memory to form an output matrix; and
determine a change to a DPD coefficient or a new DPD coefficient based on the output matrix, the change or the new DPD coefficient to cause a change in one or more of the DPD output signal and the PA feedback signal.

20. The apparatus of claim 19, wherein:
even-numbered columns of the partial matrix are stored in a first portion of memory;
odd-numbered columns of the partial matrix are stored in a second portion of memory; and
the machine-readable instructions cause the programmable circuitry to:
update, using two write operations, a first element of the output matrix in the first portion of memory and a second element of the output matrix in the second portion of memory; and
receive, using two read operations, a third element of the output matrix in the first portion of memory and a fourth element of the output matrix in the second portion of memory, wherein the two write operations and the two read operations occur in parallel.
